(19) United States
(12) Patent Application Publication
(10) Pub. No.: US 2021/0190839 A1
(43) Pub. Date: Jun. 24, 2021

(54) DEVICE AND METHOD FOR PROCESSING PARTIAL DISCHARGE TECHNICAL FIELD

(71) Applicant: ECOTOMORROW KOREA CO., LTD., Daegu (KR)

(72) Inventors: Yeon Soo LIM, Daegu (KR); Hie Ry CHOI, Daegu (KR); Se Ah CHOI, Daegu (KR)

(21) Appl. No.: 16/756,371

(22) PCT Filed: Oct. 17, 2018
(86) PCT No.: PCT/KR2018/012228

§ 371 Date: Apr. 15, 2020

(30) Foreign Application Priority Data
Oct. 17, 2017 (KR) 10-2017-0134573
Jul. 4, 2018 (KR) 10-2018-0077587

(51) Int. Cl. G01R 23/165; G01R 31/14

(52) U.S. Cl. CPC G01R 23/165; G01R 31/14

(57) ABSTRACT

This device for processing partial discharge includes: a proportional signal generation unit which generates a proportional signal which is proportional to the strength of an input signal; a transfer function generation unit which is positioned between an output end of the proportional signal generation unit and an input end of an automatic gain control unit, converts the proportional signal input to the input end on the basis of a reference voltage and a transfer function, and outputs a transfer function signal; the automatic gain control unit which performs automatic gain control when the transfer function signal is input; a partial discharge detection unit which generates an automatic gain control feedback signal through at least one RC parallel circuit to feedback the automatic gain control feedback signal to a feedback end of the automatic gain control unit, when an automatic gain control signal of the automatic gain control unit is input; and a partial discharge determination unit which filters an automatic gain control output signal on the basis of the reference voltage to generate a partial discharge determination signal, when the automatic gain control output signal of the automatic gain control unit is input.

The present invention relates to a partial discharge detection and noise removal technique and, more specifically, to a partial discharge processing device and method capable of more effectively detecting a partial discharge signal in an input signal mixed with partial discharge signal, general noise and partial discharge-like noise which is very similar to a partial discharge signal.

### BACKGROUND OF THE INVENTION

Partial discharge diagnosis techniques are used for the prevention and diagnosis of electrical equipment in power plants and in the field of electric vehicles. In general, a partial discharge diagnosis technique corresponds to a nondestructive diagnosis technique which detects electromagnetic waves, ultrasonic waves, light, or vibrations generated inside an electric device to prevent or diagnose occurrence of a partial discharge in advance.

A conventional partial discharge diagnosis technique using a electromagnetic wave is applied to a partial discharge diagnosis of a power cable using an HFCT, a partial discharge diagnosis of a power facility using a UHF sensor, a partial discharge diagnosis of an electric vehicle using an HFCT and a UHF hybrid sensor, and the like.

In the process of detecting the occurrence of the partial discharge by using the electromagnetic wave, a large amount of noise is also included, and the partial discharge signal generated by the partial discharge and the partial discharge noise or communication noise are similar, so the partial discharge are difficult to precisely distinguish, thereby significantly reducing the reliability of the partial discharge diagnosis.

The partial discharge signal input through the sensor shows a burst form of a high frequency pulse having a pulse width of several ns and there is no shaped pattern. A partial discharge-like noise burst or a communication noise burst, similar to the partial discharge signal, has a different part from the pulse constituting a cluster of partial discharge signals. However, a cable partial discharge field is not easy to detect a cable partial discharge signal because a noise signal is very similar to a cable partial discharge signal while a noise signal strength is relatively large.

Korean Patent Registration No. 10-1496442 (2015.02.17) relates to a device for diagnosing a partial discharge of a cable, and includes a detection sensor for detecting a partial discharge signal of a cable and a band pass filter for filtering out noise of the detection sensor. An amplifier for amplifying the output signal of the band pass filter, a frequency tuning filter for tuning the frequency of the output signal of the amplifier, an envelope detector for measuring the length and shape of the output signal of the frequency tuning filter, and an output of the envelope detector A peak detector for measuring the magnitude of the signal, and an analog digital signal converter for converting the output signal of the peak detector into a digital signal, and distinguishing noise and PD by checking the length and shape of the output signal of the analog digital signal converter A partial discharge signal detection unit and an output signal of the partial discharge signal detection unit through PRPD mapping It further includes a partial discharge pattern analysis unit for checking the type of partial discharge, the detection sensor is HF sensor or HF CT sensor, the measurement range is 5 MHz 200 MHz for HF sensor, the measurement range is 1 MHz 100 MHz for HFCT sensor Characterized in that, the band pass filter is a band pass filter having a pass band of 1 MHz 200 MHz, the frequency tuning filter, a signal generator for generating a signal having a frequency of 200 MHz 420 MHz.

The above technique has a disadvantage in that a partial discharge signal cannot be properly detected by filtering a partial discharge signal with a narrow band pass filter in order to remove noise. Furthermore, it has been demonstrated that noise is introduced despite the application of a band pass filter. In order to distinguish the noise and the partial discharge signal, the technique requires a high-speed ADC and a software computing process, thereby reducing economic feasibility.

The Korean Patent No. 20-0435061 (2006.12.29) relates to a partial discharge counter for diagnosing a gas insulated switchgear, comprising: a band pass filter (21-A), a peak detection circuit (21-B), a peak maintenance circuit (21-C), a frequency conversion unit for converting a signal outputted by the frequency conversion unit into a low frequency signal by using a peak reset (21-D), and a synchronizing circuit for AD-converting the signal outputted by the frequency conversion unit into an AD-converted value in the ADC (22) and matching the converted value to the frequency of the constant voltage.

The above technology also adopt the band pass filter in order to remove noise from the input signal, the partial discharge signal cannot be properly detected by filtering the partial discharge signal. Since the peak detection circuit is applied, the noise signal can be recognized as a partial discharge by recognizing the noise signal as a partial discharge when a noise larger than the partial discharge signal is introduced.

Blank

### PRIOR ART DOCUMENT

[Patent Document]

(1) Korean Patent Registration No. 10-1496442 (17 Feb. 2015)

(1) Korean Patent Registration No. 20-0435061 (29 Dec. 2006)

### DISCLOSURE

### Technical Problem

The partial discharge prevention diagnosis is necessary for life safety and facility maintenance.

Although the using electromagnetic waves method is preferable because of showing the best result for preventing partial discharge, that a new communication service is continuously provided so that noise cannot be removed by installing filter and, However, there has been an attempt to distinguish noise and partial discharge through a highspeed calculation, but it is not economical and the application has been limited.

The partial discharge signal is in the form of a burst of high frequency pulses having a pulse width of several nS and is different from the partial discharge-like noise or communication noise similar to the other partial discharge signal, but it is not easy to distinguish between the partial discharge-like noise and the partial discharge noise in the cable partial discharge field.

The present invention has been devised to solve the above-mentioned problems.

According to the present invention, a partial discharge signal is detected from an input signal in which noise is mixed in a simple partial discharge circuit configuration, so that a filter installation is not necessary and a high-speed operation process is not necessary, thereby being economical and small in volume, and thus can be used in various fields.

An embodiment of the present invention provides a partial discharge processing device and method capable of effectively detecting whether a partial discharge signal is included in an input signal.

### Technical Solutions

Among the embodiments, the partial discharge processing device comprises: a proportional signal generation unit configured to generate a proportional signal which is proportional to a strength of an input signal; a transfer function generation unit which is positioned between an output terminal of the proportional signal generation unit and an input terminal of an AGC (automatic gain control) unit, configured to convert, on the basis of a reference voltage and a transfer function, the proportional signal which is inputted into a input terminal, and output a transfer function signal; an automatic gain control unit which is configured to perform automatic gain control when the transfer function signal is inputted; a partial discharge detection unit which is configured to generates an automatic gain control feedback signal through at least one RC parallel circuit to feedback the AGC feedback signal to a feedback terminal of the AGC unit, when an automatic gain control signal of the automatic gain control unit is inputted; and a partial discharge determination unit which is configured to filter the automatic gain control output signal on the basis of the reference voltage to generate a partial discharge determination signal, when the automatic gain control output signal of the automatic gain control unit is inputted.

The proportional signal generation unit may be implemented as a log detector for demodulating a log value of the input signal to generate the proportional signal.

The proportional signal generation unit may be implemented through at least one of an amplifier, an envelope detector, and an integrator or through at least two combinations.

The partial discharge detection unit may feedback an strength of amplitude or a frequency of the automatic gain control signal to feedback terminal of the automatic gain control unit through the at least one RC parallel circuit.

Wherein in the feedback process, the partial discharge detection unit performs a negative amplification with respect to the reference voltage when a noise is included in the automatic gain control signal, and induces a temporary overamplification and fluctuation to change an amplification factor as charging, discharging and feedback effects among the at least one RC parallel circuit and the automatic gain control unit when a partial discharge signal is included.

The transfer function generation unit may have an inverse proportional transfer function for converting a value of −60 dBm to 5 dBm of the proportional signal to a value of 1.7 Vdc to 0.5 Vdc.

The reference voltage may be formed to have a value within a specific error range based on the 2.4 VDC.

The partial discharge determination unit compares the automatic gain control output signal with the reference voltage to determine and discard a signal which is less than the reference voltage in the automatic gain control output signal as noise, and may generate the partial discharge determination signal through the filtering obtained by determining and obtaining the signal which is above the reference voltage as a partial discharge.

The partial discharge determination unit is implemented with a difference amplifier which subtracts the reference voltage from the automatic gain control output signal, or implemented with a differential amplifier that differentially amplifies on the basis of the automatic gain control output signal and the reference voltage, or may include at least one diode for voltage drop in partial discharge.

The partial discharge processing device may further include a partial discharge signal level conversion unit for generating a partial discharge level conversion signal converted to a TTL transistor logic level if the amplitude of the partial discharge determination signal is equal to or greater than a reference amplitude.

The partial discharge signal level conversion unit may be implemented through at least one of a comparator and a Schmitt trigger.

Among the embodiments, the partial discharge detection method is performed by a partial discharge processing device. The partial discharge detection method comprises: a proportional signal generating step of generating a proportional signal proportional to the intensity of the input signal; a transfer function generation step of setting a reference voltage and a transfer function and converting the proportional signal based on the reference voltage and the transfer function to generate a transfer function signal; an automatic gain control step of performing Auto Gain Control on the basis of the transfer function signal; a partial discharge detection step of inducing a mutual charge/discharge and a feedback action between the at least one RC parallel circuit and the automatic gain control unit and feeding through at least one RC parallel circuit back to a process of performing the automatic gain control; and a partial discharge determination step of generating a partial discharge determination signal by filtering the automatic gain control output signal based on the reference voltage when an automatic gain control output signal is generated through the automatic gain control.

### Advantageous Effects

The disclosed technology can have the following effects. However, it is to be understood that the scope of the disclosed technology should not be construed as limited thereby, since the specific embodiments should include all the following effects or should include only the following effects.

The partial discharge processing device and method according to an embodiment of the present invention can effectively detect whether a partial discharge signal is included in an input signal.

According to an embodiment of the present invention, a partial discharge processing device and a method thereof effectively remove noise and partial discharge-like noise even when a partial discharge signal and noise and partial discharge-like noise are mixed in an input signal, thereby detecting a partial discharge.

The technical concept of the present invention is referred to as a PD Amplification Noise Attenuation (PANA) method.

According to the PANA method of the present invention, the partial discharge signal component is amplified more than the reference voltage (Vref) with respect to the partial discharge signal and the noise signal which are mixed at the same time, and the noise component is attenuated by the reference voltage (Vref) to be differentiated based on the reference intensity (Vref), and the error is very small in detecting the partial discharge signal with the differential point.

According to the PANA method of the present invention, since the intensity of the detected partial discharge signal component is proportional to the intensity of the input partial discharge signal, the PANA method can act as a partial charge sensor with only the output itself, but can be utilized as a partial discharge measurement device when the ADC is coupled. At the same time, the TTL conversion circuit can be used as a partial discharge counter or the like.

The present invention can be applied to, but is not limited to, a cable partial discharge preventive diagnosis, a solid insulated switchgear (SIS) facility partial discharge preventive diagnosis, an electric vehicle partial discharge preventive diagnosis, an electric vehicle charger partial discharge preventive diagnosis, a gas insulation dynamics (GIS) partial discharge preventive diagnosis, a UHF partial discharge sensor having a noise removal function, a bushing partial discharge preventive diagnosis, and the like.

### DESCRIPTION OF DRAWINGS

FIG. 1 is a diagram illustrating a configuration of a partial discharge processing device according to an embodiment of the present invention.

FIG. 2 is a circuit diagram of the transfer function generation unit shown in FIG. 1.

FIG. 3 is a circuit diagram of an embodiment of the partial discharge detection unit shown in FIG. 1.

FIG. 4 is a circuit diagram of other embodiments of the partial discharge detection unit shown in FIG. 1.

FIG. 5 is a diagram illustrating voltages input or output in a process of detecting a partial discharge in the partial discharge processing device shown in FIG. 1.

FIG. 6 is a circuit diagram of an embodiment of the partial discharge determination unit shown in FIG. 1.

FIG. 7 shows a partial discharge detection system including the partial discharge processing device shown in FIG. 1.

FIG. 8 is an output result graph showing a process of detecting whether a partial discharge is generated by actually implementing the partial discharge processing device shown in FIG. 7.

FIG. 9 is a diagram illustrating a partial discharge noise suppression and signal processing system according to an embodiment of the present invention.

FIG. 10 is a diagram illustrating a configuration of a partial discharge timing signal acquisition device according to an embodiment of the present invention.

FIG. 11 is a block diagram illustrating one embodiment of the configuration of the proportional signal generation unit shown in FIG. 10.

FIG. 12 is a circuit diagram of an embodiment of the transfer function generation module shown in FIG. 11.

FIG. 13 is a block diagram illustrating the configuration of the first automatic gain control unit and the second automatic gain control unit shown in FIG. 10.

FIG. 14 is a circuit diagram of other embodiments of the partial discharge feedback module shown in FIG. 13.

FIG. 15 is a circuit diagram of an embodiment of the timing noise elimination unit shown in FIG. 10.

FIG. 16 is a diagram illustrating an embodiment of voltage waveforms in which the partial discharge noise suppression and signal processing system shown in FIG. 9 receives or outputs timing noise cancellation, timing signal acquisition, partial discharge signal regeneration or generation during a partial discharge detection process.

FIG. 17 shows experimental results of removing noise and detecting partial discharge using the partial discharge noise suppression and signal processing system shown in FIG. 9.

FIG. 18 is a graph showing the result of comparing an embodiment of partial discharge noise suppression and signal processing system shown in FIG. 9 with the prior art to detect whether a partial discharge occurs.

FIG. 19 is a diagram illustrating the configuration of the partial discharge signal acquisition unit shown in FIG. 9 according to an embodiment of the present invention.

FIG. 20 is a diagram illustrating the configuration of the partial discharge signal generation unit shown in FIG. 9 according to an embodiment of the present invention.

### MODES OF THE INVENTION

The description of the present invention is intended to be illustrative, and not restrictive, and the scope of the invention should not be construed as limited by the embodiments set forth herein. That is, the embodiments are to be considered in all respects as illustrative and not restrictive, and the scope of the invention is to be understood as including equivalents to those skilled in the art. Also, it is to be understood that the scope of the invention is not to be construed as limited thereby, since the objects or effects presented in the present invention are not meant to be limited thereby.

On the other hand, the meaning of the term described in this application should be understood as follows.

The terms “first, second,” and the like are intended to distinguish one element from another, and should not be limited by these terms. For example, a first component can be termed a second component, and similarly, a second component can also be termed a first component.

It will be understood that, when an element is referred to as being “coupled to” another element, it may be directly coupled to the other element, or intervening elements may also be present. In contrast, when an element is referred to as being “directly connected to” another element, there are no intervening elements present. On the other hand, other representations that describe the relationship between the components, i.e., “between” and “directly between” and “adjacent to,” and so on, should likewise be interpreted.

When a component is referred to as being “connected” to another component, it should be understood that there may be another component in between, although it may be directly connected to the other component. On the other hand, when a component is referred to as being “directly connected” to another component, it should be understood that there is no other component in between. On the other hand, other expressions describing the relationship between the components, such as “between” and “immediately between” or “neighboring to” and “directly neighboring”, should be interpreted as well.

The identification code (for example, A, B, C, etc.) in each of the steps is used for ease of description and is not intended to describe the order of each step, and each of the steps may occur differently than the order in which the context clearly does not describe a particular order. That is, each of the steps may be performed in the same order as the specified order, may be performed substantially simultaneously, and may be performed in the opposite order.

Unless defined otherwise, all terms used herein have the same meaning as commonly understood by one of ordinary skill in the art to which this invention belongs. The terms defined in the commonly used dictionaries should be interpreted to be consistent with their meaning in the context of the relevant art and are not to be interpreted as having an idealized or overly formal meaning unless expressly so defined in this application.

Blank

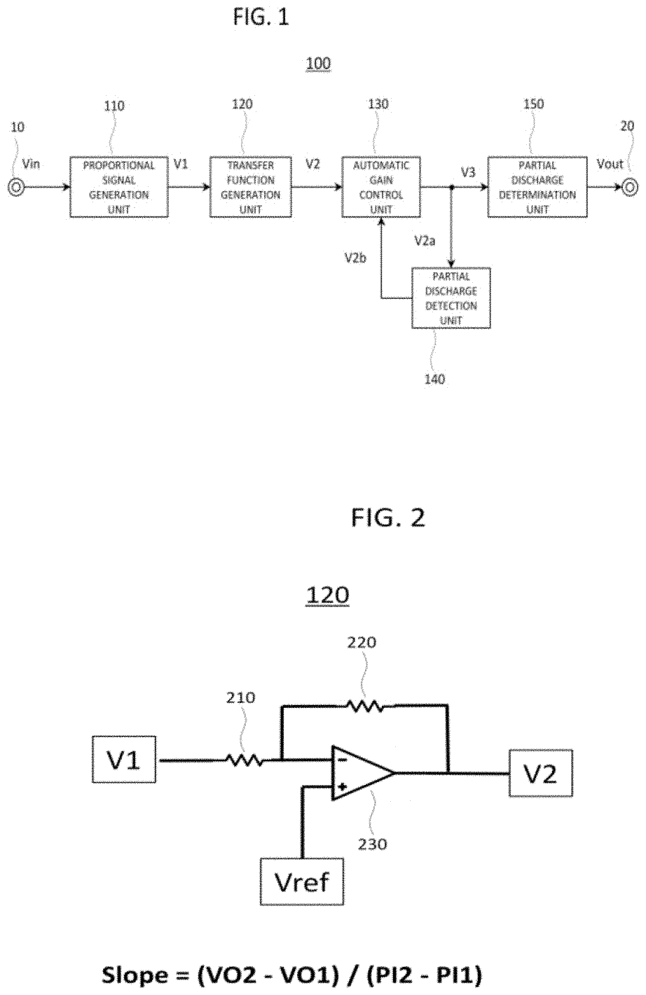

FIG. 1 is a diagram illustrating a configuration of a partial discharge processing device according to an embodiment of the present invention.

Referring to FIG. 1, the partial discharge processing device 100 may include a proportional signal generation unit 110, a transfer function generator 120, an automatic gain control unit 130, a partial discharge detection unit 140, and a partial discharge determination unit 150.

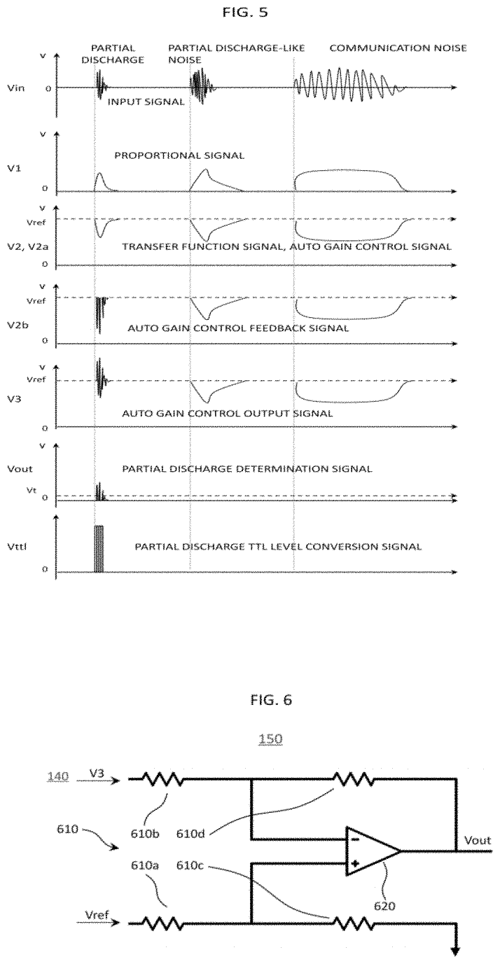

The proportional signal generation unit 110 generates a proportional signal proportional to the strength of the input signal. More specifically, the proportional signal generation unit 110 may be disposed between the input port 10 and the transfer function generator 120 to be electrically connected to an input terminal of the input port 10 and the transfer function generator 120, receive an input signal received through the input port 10 as input, and output a proportional signal proportional to the strength of at least one of the amplitude, frequency, and power of the input signal to provide the proportional signal to the input terminal of the transfer function generator 120. For example, if the input signal Vin is received, the proportional signal generation unit 110 may generate the proportional signal V1 as the DC output voltage proportional to the power appearing at the corresponding input terminal (see the graph of FIG. 5).

In one embodiment, the proportional signal generation unit 110 may be implemented as a log detector that demodulates a log value of the input signal to generate a proportional signal. Here, the log detector is referred to as a log detector, a log amplifier, a log amplifier, a logarithmic amplifier, an RF power detector, a log amplifier detector, or the like. At this time, the measurement value of the total node power in the RF input port can represent the total power to be converted to the DC including the signal, noise, interference, and the like.

In another embodiment, the proportional signal generation unit 110 may be implemented through at least one of an amplifier, an envelope detector, a diode detector, and an integrator, or through at least two combinations. For example, the proportional signal generation unit 110 may be implemented through a combination of an RF power amplifier and an envelope detector, or a combination of an amplifier and an integrator.

The transfer function generator 120 is located between an output terminal of the proportional signal generation unit 110 and an input terminal of the automatic gain control unit 130. The transfer function generator 120 is electrically connected to an output terminal of the proportional signal generation unit 110 and an input terminal of the automatic gain control unit 130 to receive an input signal from the proportional signal generation unit 110 and output an output signal to the automatic gain control unit 130.

The transfer function generator 120 converts a proportional signal inputted to an input terminal based on a reference voltage and a transfer function, and outputs a transfer function signal. In one embodiment, the transfer function generator 120 may be provided with a reference voltage Vref having a specific DC voltage level, and at least one of a range of the input/output signal, a voltage characteristic and a frequency characteristic of the output signal relative to the input signal may be defined through a transfer function indicating a linear characteristic of the input/output signals. This is described with reference to FIG. 2.

FIG. 2 is a circuit diagram of an embodiment of the transfer function generator shown in FIG. 1

Referring to FIG. 2, the transfer function generator 120 may include first and second resistors 210 and 220, and an amplifier 230. The first resistor 210 may be disposed between the input terminal and the first input terminal of the amplifier 230, and the second resistor 220 may be disposed between the second input terminal and the output terminal of the amplifier 230, and in one embodiment, each may be formed with a resistance value of several kOhm. The amplifier 230 may receive the proportional signal V1 from the proportional signal generation unit 110 through the first resistor 210, receive the reference voltage Vref to the second input terminal, perform amplification based on feedback through the second resistor 220, generate a transfer function signal V2 corresponding to the transfer function characteristic, and output the generated transfer function signal V2 based on the reference voltage Vref (see the graph of FIG. 5).

The transfer function generator 120 may be implemented to have the characteristics of a transfer function that is proportional or inversely proportional to the total RF sweep signal power at which the DC output voltage appears at the corresponding detector input. In one embodiment, the transfer function generator 120 may be defined with a transfer function characteristic based on the following equation: (NB) where slope represents the DC output slope characteristic of the output signal versus the power appearing at the input defined in the transfer function. Here, VO1 and VO2 are output voltages, and PI1 and PI2 are signal powers appearing at input terminals.

Slope=(VO2−VO1)/(PI2−PI1) Equation 1

In one embodiment, the transfer function generator 120 may have a inverse proportional transfer function that converts the −60 dBm to +5 dBm value of the proportional signal V1 to a value of from 1.7 VDC to 0.5 VDC. At this time, the reference voltage Vref may be formed to be within the range of about 2.4 VDC, and may be formed to be within a specific reference error range, for example, on the basis of 2.4 VDC.

In another embodiment, the transfer function generator 120 may have a proportional transfer function that converts the −60 dBm to +5 dBm value of the proportional signal V1 to a value of 0.5 VDC to 1.7 VDC. At this time, the reference voltage Vref can be formed to be in the range of about 0.5 VDC.

When the transfer function signal is input, the automatic gain control unit 130 performs an AGC (auto gain control). More specifically, the automatic gain control unit 130 outputs an automatic gain control signal that can be generated based on the transfer function signal and fed back to the feedback terminal, and can perform automatic gain control based on the automatic gain control feedback signal fed back to the feedback terminal.

The automatic gain control unit 130 may be electrically connected to the output terminal of the transfer function generator 120, the input/output terminal of the partial discharge detection unit 140, and the input terminal of the partial discharge determination unit 150, and may be connected through at least one resistor in one embodiment. For example, the automatic gain control unit 130 receives the proportional signal V2 from the transfer function generator 120, transmits the automatic gain control signal V2a to the input terminal of the partial discharge detection unit 140, and simultaneously receives the automatic gain control feedback signal V2b output from the partial discharge detection unit 140 as an input to the feedback terminal and controls the voltage gain to output the automatic gain control output signal V3 (see the graph of FIG. 5).

In one embodiment, the automatic gain control unit 130 may be implemented with an Automatic Volume Control (AGC) or Automatic Volume Control (AGC), which is a closed loop feedback control circuit that provides a controlled signal amplitude based on the amplitude variation of the signal fed back at the output despite changes in the amplitude of the input signal. An automatic gain control unit 130 reduces the volume of a signal outputted by reducing a gain when the intensity of an input signal is strong, increases a gain of a signal, increases a volume of an output signal, and dynamically controls an input/output gain based on an average signal level or a maximum output signal level of an automatic gain control feedback signal fed back to a feedback terminal.

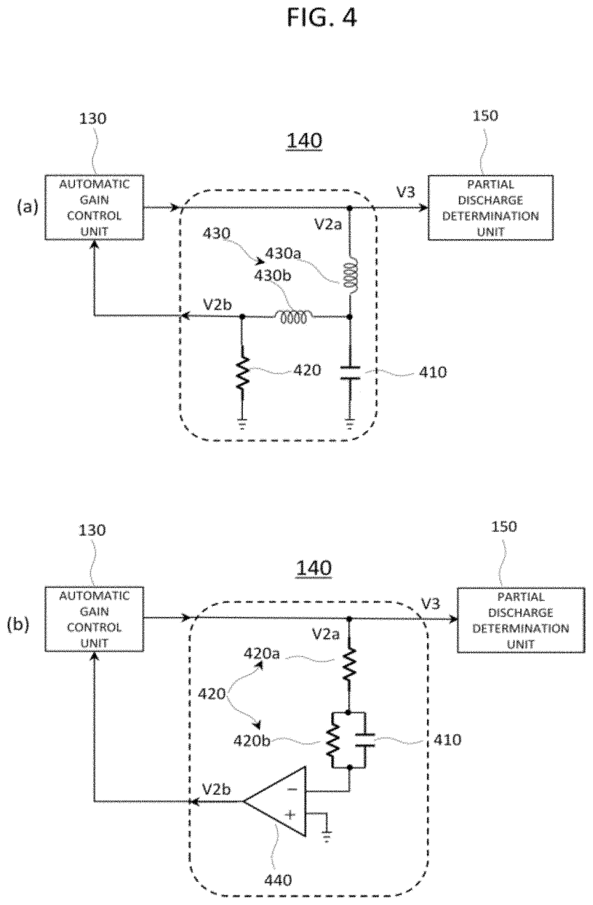

For example, the automatic gain control unit 130, if the partial discharge signal is included in the output automatic gain control signal V2a, The automatic gain control feedback signal V2B modified with respect to the transfer function signal V2 or the automatic gain control signal V2A is fed back to further control the voltage gain through the partial discharge detection unit 140, so that the controlled automatic gain control signal V2a can be further output (see the partial discharge signal detection case of FIG. 4). If not included, the automatic gain control signal V2a, which is not modified but not modified or modified to be less than the reference difference amount, can be feedback to output the less controlled automatic gain control signal V2a, and consequently, the automatic gain control signal V2a having different waveform characteristics can be output depending on whether the partial discharge signal is included (see FIG. 4, like noise or communication noise generation case).

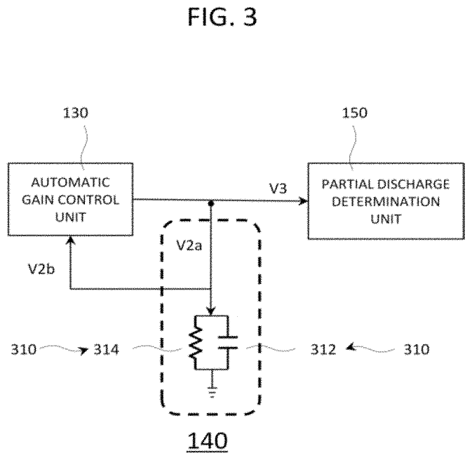

In one embodiment, the automatic gain control unit 130 may control to output an automatic gain control signal and an automatic gain control output signal with a voltage gain corresponding to the calculated voltage gain control factor g by calculating a voltage gain control factor g based on Equation 2 below, and may control the voltage gain control factor g in real time according to feedback through the partial discharge detection unit 140 to reflect the voltage gain control. For example, assuming a partial discharge occurrence situation, as shown in FIG. 3, the automatic gain control unit 130. The automatic gain control signal V2a outputted in real time is the partial discharge detection unit 140. The automatic gain control feedback signal V2b whose amplitude and frequency are modified by the operation of the partial discharge detection unit 140 is fed back to the automatic gain control signal V2a by the operation of the partial discharge detection unit 140, so that the voltage gain can be temporarily increased, and the automatic gain control output signal V3 can be temporarily over amplified at the corresponding time point according to the feedback reflection. In one embodiment, the automatic gain control unit 130 may perform an automatic gain control so that an average voltage gain is 1 when such transient overload is not generated.

$$g = \frac{{v}_{1}^{′}}{{v}_{f 1}^{′}} \\ {v}_{f 1} = g \times {v}_{1}^{′} \qquad Equation 2$$

The partial discharge detection unit 140 performs feedback through at least one RC parallel circuit 310 connected to the output terminal of the automatic gain control unit 130. This is described with reference to FIG. 3.

FIG. 3 is a circuit diagram of an embodiment of the partial discharge detection unit shown in FIG. 1.

Referring to FIG. 3, the partial discharge detection unit 140 may include at least one RC parallel circuit 310, and each of the at least one RC parallel circuit 310 may include at least one capacitor 312 and at least one resistor 314.

When the automatic gain control signal of the automatic gain control unit 130 is inputted, the partial discharge detection unit 140 generates an automatic gain control feedback signal through at least one RC parallel circuit 310 to feed back to the feedback terminal of the automatic gain control unit 130. In one embodiment, the partial discharge detection unit 140 can feed back the amplitude or frequency of the automatic gain control signal to the feedback terminal of the automatic gain control unit 130 through at least one RC parallel circuit 310, and when the partial discharge signal is included in the automatic gain control signal, as described above, the amplification degree g of the automatic gain control unit 120 can be changed by the charge-discharge and feedback operation between the automatic gain control unit 120 and the RC parallel circuit 310, thereby inducing temporary over-amplification and fluctuation.

More specifically, the partial discharge signal is a burst composed of a high frequency component having a pulse width of several ns, while noise can be viewed as a cluster of relatively low frequency components having a wide pulse width. As an example, through the log detector circuit, the partial discharge burst is in the form of an impulse, and noise is in the form of a smooth triangular wave. The impulse type waveform is composed of a high frequency component in a spectrum, and the smooth triangular wave is composed of a relatively low frequency component so that the response in the RC parallel circuit 310 is different. In one embodiment, the impulse responses to the RC parallel circuit 310 consisting of a particular R value and a C value, but the smooth triangular wave does not react (see the graph of FIG. 5).

When the partial discharge detection unit 140 receives the automatic gain control signal from the output terminal of the automatic gain control unit 130, the partial discharge detection unit 140 through an RC parallel circuit 310 comprised with a capacitor 312 and a resistor 314 each having an appropriate value and connected to the corresponding output terminal and includes forms charge-discharge feedback, and can lower the intensity of eventually a output signal result from lower the high frequency contents included in a feedback of automatic control signal, and, can let automatic gain control unit 130 generate temporarily over-amplification and fluctuation as a feedback by feed backing a automatic gain control signal in which high frequency content is lowered to automatic gain control unit 130.

The partial discharge detection unit 140 may be implemented through various configurations of the following embodiments.

In the first embodiment, partial discharge detection unit 140 may be comprised of a single RC parallel circuit 310 comprised of a single capacitor 312 and a single resistor 314. For example, the RC parallel circuit 310 may include a capacitor 312 and a resistor 314 of which one end is connected to the output terminal of the automatic gain control unit 130 and the other end of the RC parallel circuit 310 is grounded. The partial discharge detection unit 140 can filter a specific frequency band of the received automatic gain control signal through the RC parallel circuit 310, and feedback the automatic gain control feedback signal, which is filtered by a signal of a frequency band of 1 MHz to 10 GHz, to the feedback terminal of the automatic gain control unit 130. In one embodiment, the capacitor 312 can be designed to have a capacitance value of 30 pF to 300 pF, and the resistor 314 can be designed to have a value of several hundred kOhm at a few kOhm according to the design range of the capacitor 312, and can be designed to have a resistance value of, for example, 20 kOhm to 40 kOhm, and can control and vary the element value in consideration of the length pattern width of the pattern in the PCB pattern design and the dielectric constant of the material.

The partial discharge detection unit 140 may function as a low-pass filter (LPF) through the coupling configuration of the capacitor 312 and the resistor 314, and may feedback the automatic gain control unit 130 with an automatic gain control feedback signal V2b having a signal higher than 500 MHz in the automatic gain control signal V2a.

In a second embodiment, the partial discharge detection unit 140 may be comprised of at least two of a capacitor, an inductor, a resistor, and an amplifier. The partial discharge detection unit 140 may be implemented with a low pass filter (LPF) or a high pass filter (HPF) through this combination.

For example, as shown in FIG. 4(a), the partial discharge detection unit 140 may include a capacitor 410, a resistor 420, and an inductor 430, and may function as an LPF through such a coupling configuration. At this time, the at least one partial discharge inductor 430 can be designed to have an inductance value ranging from a few nH to a few mH depending on the design range of the resistor 420 and the capacitor 410.

For example, as shown in FIG. 4(b), the partial discharge detection unit 140 may include a capacitor 410, a resistor 420, and a partial discharge amplifier 440, and may function as an LPF through such a coupling configuration.

Although several exemplary configurations for implementing the partial discharge detection unit 140 have been described above, it should be understood that the partial discharge detection unit 140 can be configured in various forms necessary with respect to the function of inducing an over-amplification and a fluctuation operation when the partial discharge is generated by modifying the output signal received from the automatic gain control unit 130 for partial discharge detection and feeding back the modified output signal to the automatic gain control unit 130.

The partial discharge detection unit 140 feeds back the output automatic gain control signal to the automatic gain control unit 130 and simultaneously transmits the automatic gain control output signal to the partial discharge determination unit 150. In one embodiment, the partial discharge detection unit 140 may further include a resistance of a few kOhm disposed between an output terminal of the partial discharge detection unit 140 and an input terminal of the partial discharge determination unit 150 for outputting an automatic gain control output signal for controlling the output impedance.

When the automatic gain control output signal of the automatic gain control unit 130 is inputted, the partial discharge determination unit 150 can generate a partial discharge determination signal by filtering the automatic gain control output signal based on the reference voltage. For example, the partial discharge determination unit 150 may buffer or amplify or subtract only a portion of the automatic gain control output signal based on the reference voltage to obtain a partial discharge determination signal. The partial discharge determination unit 150 may be electrically connected to the output terminal of the automatic gain control unit 130, the input terminal of the partial discharge detection unit 140, and the output port 20.

In one embodiment, the partial discharge determination unit 150 may compare the automatic gain control output signal with the reference voltage to determine a signal less than the reference voltage in the automatic gain control output signal as noise, and determine a signal above the reference voltage as a partial discharge and generate a partial discharge determination signal through filtering. For example, the partial discharge determination unit 150 processes a signal having an intensity of less than the reference voltage Vref from the automatic gain control output signal V3 to a noise, acquires a signal having an intensity above the reference voltage Vref as a partial discharge, generates a partial discharge determination signal Vout, and outputs the partial discharge determination signal Vout to the output port 20 (see the graph of FIG. 5).

In one embodiment, in order to generate a partial discharge determination signal, the partial discharge determination unit 150 generates a partial discharge determination signal by subtracting a reference voltage or a certain specific voltage from an automatic gain control output signal by a difference amplifier operated with +5 Vdc single power supply, or, and the present invention can be implemented as a differential amplifier which generates a partial discharge determination signal by differentially amplifying a voltage based on an automatic gain control output signal and a reference voltage or a certain specific voltage, or can be implemented through one or more diode connections to remove a noise component and generate a partial discharge determination signal by dropping a voltage of an automatic gain control output signal to a certain specific voltage or a reference voltage or a reference voltage below a reference voltage when a partial discharge occurs.

In one embodiment, the partial discharge processing device 100 may further include a partial discharge signal level conversion unit (not shown). The partial discharge signal level conversion unit may be electrically connected to an output terminal of the partial discharge determination unit 150 and the output port 20, and may receive an automatic gain control output signal output from the partial discharge determination unit 150 to generate a partial discharge level conversion signal.

The partial discharge signal level converter generates a partial discharge level conversion signal which is converted to a TTL transistor logic level if the amplitude of the automatic gain control output signal is equal to or greater than a reference amplitude. In one embodiment, the partial discharge level conversion signal can be designed to have a specific amplitude and duration, wherein the reference amplitude can be set by the designer based on a design target relating to accuracy and speed, and design values of the internal components can be controlled to have a corresponding reference amplitude.

In one embodiment, the partial discharge level conversion signal can be implemented including at least one of a comparator and a Schmitt trigger for TTL level conversion. For example, the partial discharge level conversion signal may be implemented through at least one combination of a comparator for generating a particular voltage level (for example, in a clock unit) for a particular duration of time, meaning data 1 when the voltage level of the automatic gain control signal exceeds the voltage level of the reference voltage Vt, a level trigger for triggering whether the output of the comparator represents a data 1, or a level shifter for controlling the voltage level. In one embodiment, the reference voltage Vt may be set in a range between 50% and 90% relative to the maximum voltage level or at any particular level.

According to the above procedure, the partial discharge signal level conversion unit generates a signal of an analog level generated in a partial discharge detection process to make a TTL level signal for processing a digital signal to more clearly inform a user of the occurrence of a partial discharge, and can be used as an input for digital processing in a subsequent step. In addition, the partial discharge signal level conversion unit buffers an analog level signal and provides the buffered signal to an ADC (Analog Digital Converter) input terminal to measure the output intensity.

In one embodiment, the partial discharge determination unit 150 may further include a network communication module, and may output a warning sound when a partial discharge determination signal or a partial discharge level conversion signal is generated, and transmit a notification message related to the corresponding occurrence and information about the corresponding waveform to a monitoring server (not shown) connected to the network through the network communication module. In addition, the intensity of the partial discharge is measured by using the ADCconverted digital signal, and the partial discharge intensity change monitoring (not shown) can be monitored and utilized as equipment remote monitoring and remote preventive diagnosis equipment by analyzing the intensity of the partial discharge according to the intensity of each time zone.

Blank

FIG. 5 is a diagram illustrating voltages input or output in a process of detecting a partial discharge in the partial discharge processing device shown in FIG. 1.

In FIG. 3, partial discharge processing device 100 may receive an input signal Vin via input port 10, and proportional signal generation unit 110 may generate a proportional signal V1 that is proportional to the strength of input signal Vin (e.g., demodulates a log value of Vin). For example, the portion corresponding to the partial discharge signal among the RF burst signals, which have been de-modulated by the proportional signal generation unit 110, may be output as a proportional signal V1 having a waveform close to a very narrow waveform width (e.g., an impulse), and other noise other than the partial discharge may be output to the proportional signal V1 having a relatively slow waveform.

As shown in FIG. 2, the transfer function generator 120 may generate the transfer function signal V2 according to a characteristic of a slope (e.g., SLOPE=(VO2−VO1)/(PI2−PI1)) of a predetermined reference voltage Vref and a transfer function. Where P is the intensity of the RF burst input of the proportional signal generation unit 110.

The automatic gain control unit 130 may output the automatic gain control signal V2a based on the transfer function signal V2. Partial discharge detection unit 140) The automatic gain control unit 130 generates an automatic gain control feedback signal V2b that temporarily drops a voltage in the high frequency band from the automatic gain control signal V2a through the RC parallel circuit 310 connected to the output terminal of the automatic gain control unit 130 to provide the automatic gain control feedback signal V2b to the feedback terminal of the automatic gain control unit 130, and the automatic gain control unit 130 can amplify the amplitude of the automatic gain control signal V2a outputted while the corresponding drop continues by increasing the voltage gain if the temporarily dropped automatic gain control feedback signal V2b is fed back.

In the case where the partial discharge signal is generated, the partial discharge detection unit 140 can output the modified automatic gain control output signal V3 by inducing an over-amplification of the automatic gain control unit 130 when a partial discharge signal is generated, and can output an automatic gain control output signal V3 which is not modified in effect by not inducing an over-amplification of the automatic gain control unit 130 when similar noise or communication noise is generated. In FIG. 3, although V2a, V2b, and V3, which may be generated by the partial discharge detection unit 140, are separately displayed, in one embodiment, at least some of the V2a, V2b, and V3 may correspond to the same node according to the configuration of the partial discharge detection unit 140.

If the amplitude of the automatic gain control output signal V3 received from the partial discharge detection unit 140 is equal to or greater than the reference voltage Vref, the partial discharge determination unit 150 may determine the corresponding portion as a partial discharge signal and generate the partial discharge determination signal Vout in a manner that the corresponding portion is determined as a noise signal when the amplitude of the automatic gain control output signal V3 is less than the reference voltage Vref.

However, since the noise component may remain partially, the partial discharge signal level converter compares the partial discharge determination signal Vout received from the partial discharge determination unit 150 with another reference voltage Vt to generate a partial discharge level conversion signal Vttl of the TTL level when a signal having an amplitude greater than or equal to the Vt is detected. Accordingly, the partial discharge processing device 100 can selectively inform whether the partial discharge is generated depending on whether a partial discharge signal is included in the input signal.

Blank

FIG. 6 is a circuit diagram of the partial discharge determination unit shown in FIG. 1.

Referring to FIG. 6, the partial discharge determiner 150 may be configured with a subtraction amplifier that receives the automatic gain control output signal as a first input, receives Vref as a second input, and subtracts the second input at the first input. In one embodiment, the partial discharge determiner 150 may function as a subtraction to amplify a difference in the intensity of the positive input to a voltage gain 1 using an operational amplifier, and in another embodiment, may function as a differential amplifier that uses an operational amplifier to amplify the difference in intensity of the positive input to a voltage gain greater than or equal to 1.

In one embodiment, the partial discharge determination unit 150 includes a plurality of resistors 510 connected to a first input terminal in which an automatic gain control output signal is received or a second input terminal in which Vref is received. For example, the partial discharge determination unit 150 may include a first resistor 610b disposed between the Vref and the first input terminal, a second resistor 610a disposed between an output terminal of the partial discharge detection unit 140 and the second input terminal, a third resistor 610d disposed between the first input terminal and an output terminal of the partial discharge determination unit 150, and a fourth resistor 610c disposed between the second input terminal and the ground. In one embodiment, the plurality of resistors 610 may be designed to have the same resistance value within a resistance range of several kOhm.

In another embodiment, the partial discharge determination unit 150 may be implemented as a differential amplifier that differentially amplifies the automatic gain control signal and the reference voltage Vref.

Blank

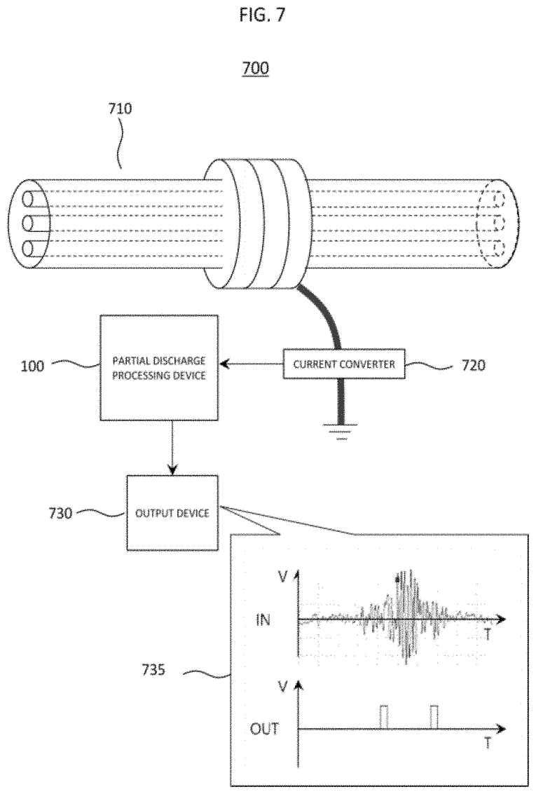

FIG. 7 shows a partial discharge detection system including the partial discharge processing device shown in FIG. 1.

The partial discharge detection system 700 may include an electric device 710, a current converter 720, a partial discharge processing device 100, and an output device 730.

The electrical equipment 710 may correspond to a power plant device that performs at least one of electric, power generation, electrical conversion, electricity supply, and electrical control. For example, the electrical equipment 710 may correspond to a cable partial discharge device that includes a solid state insulation oscilloscope (SIS). In FIG. 7, the electric device 710 is shown in the form of a gas insulated switchgear, but may correspond to a battery, an inverter, a power motor, a charger for an electric vehicle, a transformer, or a cable on an electric vehicle, and may correspond to a high-speed electric steel or a building distribution and an ultra-high frequency (UHF) association device.

The current converter 720 may be coupled to a ground line of the electric device 710, and may be implemented as a CT device for detecting an electromagnetic wave generated by the electric device 710 and converting it into a current, and the partial discharge processing device 100 may receive the current converted from the current converter 720 as an input signal and perform partial discharge detection based on the input signal.

The output device 730 may be coupled to the partial discharge processing device 100 and may process and visualize signals received from the partial discharge processing device 100. In one embodiment, the output device 730 may be implemented via at least one of a digital conversion module capable of converting analog signals received from the partial discharge processing device 100 into a digital signal, a field-programmable gate array (FPGA) implemented to be programmable based on the converted digital signal, a PC board for processing a signal received from the FPGA manufacturer, and a display module for visually outputting the processed signal.

Blank

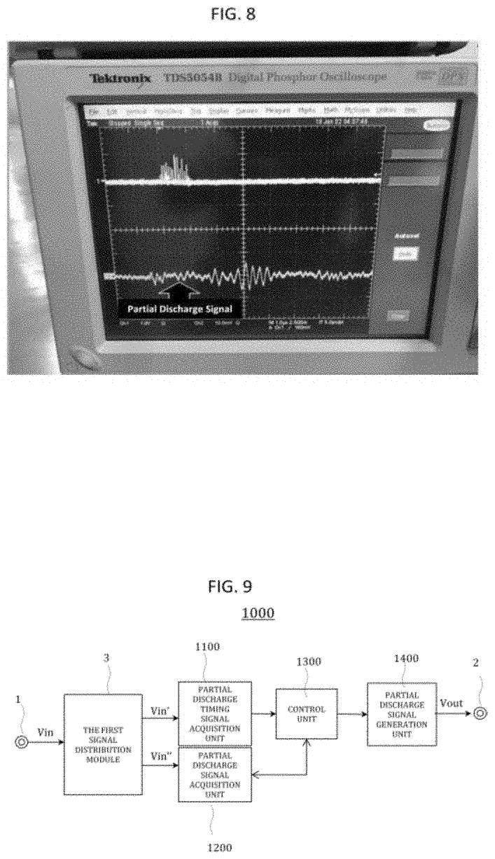

FIG. 8 is an output result graph showing a process of detecting whether a partial discharge is generated by actually implementing the partial discharge processing device shown in FIG. 7.

In FIG. 8, the partial discharge processing device 100 may be implemented with actual equipment to receive a target signal as an input signal from a current converter 720 connected to the electrical equipment 710 of the SIS equipment, process the provided input signal to detect whether a partial discharge signal is included, and visualize the corresponding input/output signal through the output device 730.

In FIG. 8, the lower graph shows the input signal Vin provided from the current converter 720, and the above graph shows the output signal Vout generated by detecting whether the partial discharge signal is generated based on the input signal. According to an embodiment of the present invention, the partial discharge processing device 100 detects whether a partial discharge signal is included in the provided input signal Vin.

Blank

FIG. 9 is a diagram illustrating a partial discharge noise suppression and signal processing system according to one embodiment.

Referring to FIG. 9, the partial discharge noise suppression and signal processing system 1000 may include an input terminal 1, an output terminal 2, a first signal distribution module 3, a partial discharge timing signal acquisition unit 1100, a control unit 1300, a partial discharge signal acquisition unit 1200, and a partial discharge signal generation unit 1400.

The partial discharge noise suppression and signal processing system 1000 can detect a partial discharge generation timing in an ultra-short PANA-timing manner and remove a signal independent of the timing generation, unlike a previous stage filter method and/or a back-end high-speed software processing method in an input signal in which a partial discharge signal and noise are mixed, thereby effectively removing a partial discharge signal by effectively removing noise and effectively removing noise. In the process of detecting the partial discharge signal, the noise suppression having the characteristic of acquiring and analyzing a signal of −65 dBm or less, which is a very fine signal, is an important factor that depends on the success of the partial discharge signal detection, and thus it is difficult to suppress such noise even in any prior art because of the similar partial discharge signal which is very similar to the partial discharge signal. All signals including noise are able to suppress noise because only a partial discharge can be detected if only a partial discharge generation timing can be accurately detected with a constant signal width. A partial discharge noise suppression and signal processing system 1000 is provided to reproduce a partial discharge signal in which noise is removed by obtaining only a partial discharge signal by measuring a partial discharge size at the same time as obtaining a partial discharge generation timing, and to use the partial discharge signal in various devices.

In one embodiment, the control unit 1300 can be implemented by applying a microprocessor and the partial discharge signal acquisition unit 1200 can be implemented by applying an analog-to-digital converter (ADC). The ADC algorithm obtains the signal size according to the command of the control unit 1300 and passes it to the control unit 1300.

In one embodiment, the partial discharge signal generation unit 1400 may apply a Digital to Analog Converter (DAC). The magnitude of the signal at the occurrence of the DAC jam signal can be provided by providing or amplifying or attenuating the partial discharge signal magnitude obtained from the ADC to the same size in the control unit 1300. When the DAC signal is generated, the signal magnitude, the burst period, the frequency, and the waveform can be determined in the control unit 1300.

As a result, the partial discharge noise suppression and signal processing system acquires the partial discharge generation timing through the partial discharge timing signal acquisition unit 1100, detects the magnitude of the partial discharge signal with the ADC, detects the magnitude, the burst period, the frequency, and the waveform, which are the same or different from the detected partial discharge signal magnitude, can be determined by the controller, and only the partial discharge signal can be reproduced or produced by the DAC, thereby effectively suppressing noise and detecting the partial discharge signal. As a result of the experiment, since the timing signal is generated at the occurrence of the partial discharge signal (the occurrence of the partial discharge signal period), very accurate noise processing and partial discharge acquisition are possible. According to the present invention, the effect of the present invention is achieved by using the timing result.

In one embodiment, the partial discharge noise suppression and signal processing system obtains a partial discharge generation timing and simultaneously acquires only a partial discharge signal by measuring a partial discharge size, thereby reproducing a partial discharge signal in which noise is removed, and can be used in various devices.

In one embodiment, the partial discharge noise suppression and signal processing system can be used for an active partial discharge detection sensor module having a noise removal function by obtaining a partial discharge generation timing and measuring a partial discharge size at the same time to reproduce and transmit a partial discharge signal.

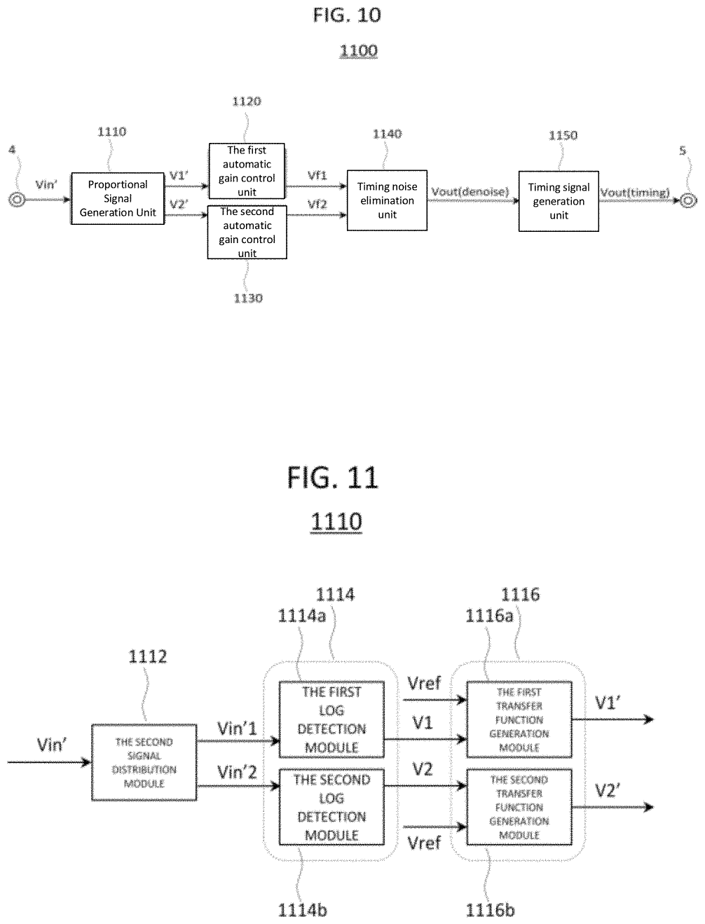

FIG. 10 is a diagram illustrating a configuration of a partial discharge timing signal acquisition unit according to an embodiment of the present invention.

Referring to FIG. 10, the partial discharge timing signal acquisition unit 1100 may include a proportional signal generation unit 1110, a first automatic gain control unit 1120, a second automatic gain control unit 1130, a timing noise elimination unit 1140, and a timing signal generation unit 1150.

The proportional signal generation unit 1110 generates first and second proportional signals according to an input signal. More specifically, the proportional signal generation unit 1110 The input port 4 is electrically connected to the input port 4 to receive the input signal through the input port 4, and the first and second proportional signals can be generated based on the received input signal, and the first and second proportional signals generated by being electrically connected to the input terminal of the first and second automatic gain control units 1120, 1130 at the output terminal can be provided to the input terminal of the first and second automatic gain control units 1120, 1130, respectively.

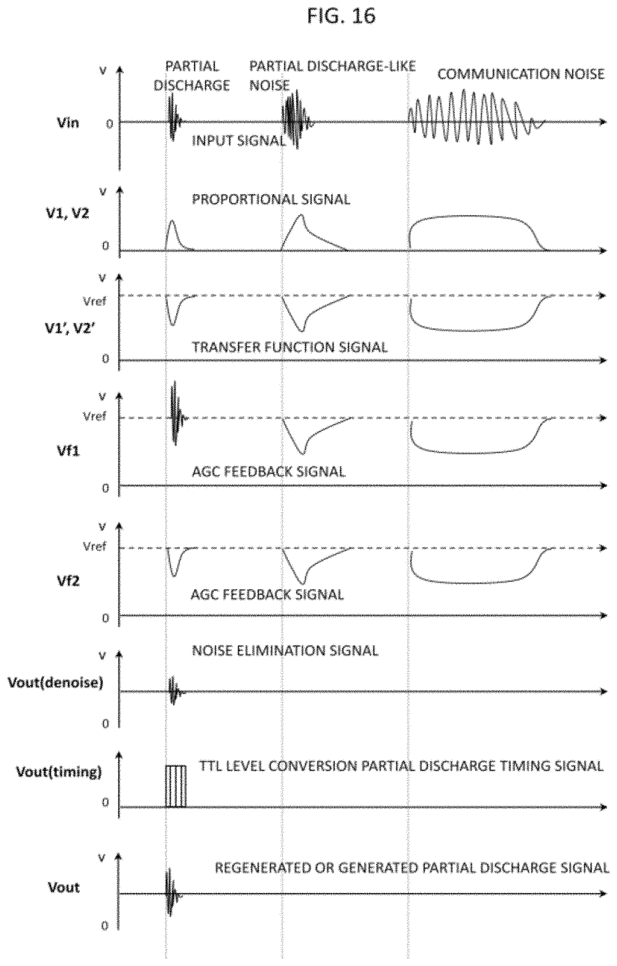

In one embodiment, the proportional signal generation unit 1110 may generate first and second proportional signals proportional to the strength of at least one of the amplitude, frequency, and power of the input signal, for example, when the input signal Vin′ is received, it may generate the proportional signal V1′ and V2′ as the DC output voltage proportional to the power appearing at the corresponding input stage (see the graph of FIG. 16). This is described in more detail with reference to FIG. 11.

FIG. 11 is a block diagram illustrating one embodiment of the configuration of the proportional signal generation unit shown in FIG. 10.

Referring to FIG. 11, the proportional signal generation unit 1110 may include a second signal distribution module 1112, first and second log detection modules 1114, and first and second transfer function generation modules 1116.

The second signal distribution module 1112 can divide the input signal by at least two and, in one embodiment, can generate at least two signals having the same phase and amplitude magnitude as the corresponding signal based on the input signal. The second signal distribution module 1112 can be electrically connected to the input terminal of the first and second log detection modules 1114 at the output terminal, and the input signal Vin received through the input port 4 can be provided to the first log detection module 1114a and the second log detection module 1114b, respectively, by generating two signals Vin′1 and Vin′2 having the same phase and amplitude based on the output signal Vin′ of the first signal distribution module.

In one embodiment, the second signal distribution module 1112 may include an amplifier (not shown) that amplifies an input signal to a predetermined specific power gain (e.g., 10 dB), may distribute the amplified signal to a plurality of signals through the corresponding amplifier, and may be implemented as a 1:N dB (N ∞ is a natural number greater than or equal to 2).

The first and second log detection modules 1114 can generate first and second proportional signals to be proportional to a magnitude of at least one of an amplitude, a frequency, and a power of the input signal. In one embodiment, the first and second log detection modules 1114 may be configured with a number corresponding to the signal distribution number of the second signal distribution module 1112, and may be configured with first to third log detection modules, for example, where the second signal distribution module 1112 is implemented as a 1:3 distributor. First log detection module 1114a The first signal Vin′1 distributed from the second signal distribution module 1112 may be input, the second log detection module 1114b may receive the second signal Vin′2 distributed from the signal distribution module 1112, and each of the first and second log detection modules 1114 may generate the first and second proportional signals V1 and V2, respectively, as a DC complementary output voltage proportional to the signal power appearing at the corresponding input terminal (see the graph of FIG. 16).

In one embodiment, each of the first and second log detection modules 1114 may be implemented with a log detector that demodulates the log value of the incoming signal to produce an output signal. Here, the log detector is referred to as a log detector, a log amplifier, a log amplifier, a logarithmic amplifier, an RF power detector, a log amplifier detector, or the like. At this time, the measurement value of the total node power in the RF input port can represent the total power to be converted to DC including the signal, noise, and interference.

In another embodiment, each of the first and second log detection modules 1114 may be implemented via at least one of an amplifier, an envelope detector, a diode detector, and an integrator, or may be implemented via at least two combinations, for example, via a combination of an RF amplifier and an envelope detector or via a combination of an amplifier and an integrator.

Each of the first and second transfer function generation modules 1116 may output a transfer function signal by converting a proportional signal input to an input terminal based on a reference voltage and a transfer function. The first transfer function generation module 1116a receives the first proportional signal V1 from the first log detection module 1114a and generates a first transfer function signal V1′ based on the reference voltage Vref and the transfer function to generate a first automatic gain. The second transfer function generation module 1116b may receive the second proportional signal V2 from the second log detection module 1114b based on the same transfer voltage as the same reference voltage Vref. The second transfer function signal VT may be generated and output to the input terminal of the second automatic gain control unit 1130 (see the graph of FIG. 16).

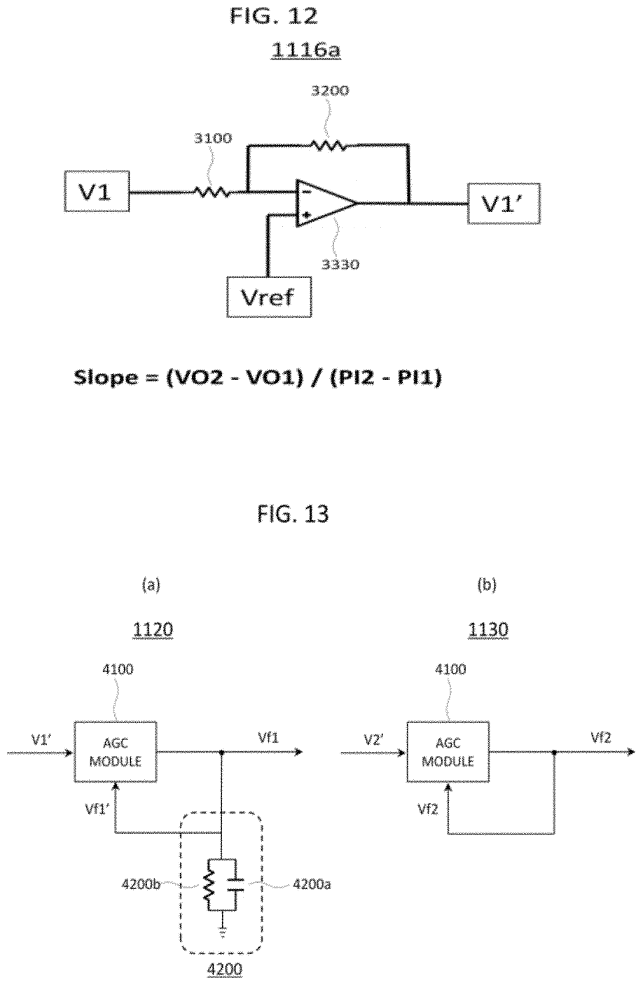

Each of the first and second transfer function generation modules 1116 may be provided with a reference voltage Vref having a specific DC voltage level, and at least one of a range of the input/output signal, a voltage characteristic and a frequency characteristic of the output signal relative to the input signal may be defined through a transfer function indicating a linear characteristic of the input/output signals. Here, the transfer function can be designed by a designer or user, and the reference voltage can be controlled by the user to the input value and range. This is described in more detail with reference to FIG. 12.

FIG. 12 is a circuit diagram of the transfer function generation module shown in FIG. 11.

Referring to FIG. 12, the first and second transfer function generation modules 1116 may include first and second resistors 3100 and 3200 and an amplifier 3300.

The first resistor 3100 may be disposed between the input terminal and the first input of the amplifier 3300, and the second resistor 3200 may be disposed between the second input and the output of the amplifier 3300, and in one embodiment, each may have a resistance value of several KOhm.

The amplifier 3300 may receive a proportional signal from one of the first and second log detection modules 1114 via the first resistor 3100 at a first input terminal, receive a reference voltage Vref at a second input terminal, perform amplification based on feedback through the second resistor 1400 to generate and output a transfer function signal V1′ (or V2′) corresponding to the transfer function characteristic (see the graph of FIG. 16). Accordingly, the amplifier 3300 may output a transfer function signal reduced by a magnitude corresponding to the proportional signal input based on the reference voltage Vref.

Each of the first and second transfer function generation modules 1116 may be implemented such that the DC output voltage has a characteristic of a transfer function that is proportional or inversely proportional to the total RF signal power appearing at the corresponding detector input. In one embodiment, each of the first and second transfer function generation modules 1116 may be implemented through a differential amplifier that receives an inverted input signal and a non-inverted input signal as input signals, based on Equation 3 below. We can determine the characteristics of the transfer function that define the scope of operation of the transfer function generation module. Here, slope represents a DC output slope characteristic of an output signal versus a power appearing at an input terminal defined by a transfer function. Here, VO1 and VO2 refer to output voltages output from two output stages, and PI1 and PI2 refer to signal powers appearing at both input stages.

Slope=(VO2−VO1)/(PI2−PI1) Equation 3

In one embodiment, each of the first and second transfer function generation modules 1116 may have a inverseproportional transfer function that converts the −60 dBm to +5 dBm value of the corresponding input proportional signal to a value other than 1.7 dB DC to 0.5 dB DC. At this time, the reference voltage Vref may be formed to be within the range of about 2.4V DC, and may be formed to be within a specific reference error range based on, for example, 2.4 VDC.

In another embodiment, each of the first and second transfer function generation modules 1116 may have a proportional transfer function that converts the −60 dBm to +5 dBm value of the corresponding input proportional signal to a value of 0.5 to 1.7 dB DC. At this time, the reference voltage Vref can be formed to be in the range of about 0.5 dB DC.

Although the signal distribution module 1112, the first and second log detection modules 1114, and the first and second transfer function generation modules 1116 are sequentially arranged in the above, the proportional signal generation unit 1110 can be implemented through at least some of these, and the arrangement order, the arrangement number, and the connection structure of the components can be implemented in various circuit types through various embodiments for generating a plurality of proportional signals proportional to the amplitude, frequency, or magnitude of the input signal.

The first automatic gain control unit 1120 performs automatic gain control on the partial discharge detection signal generated based on the first proportional signal and fed back to the input terminal through the at least one partial discharge capacitor. The first automatic gain control unit 1120 can perform automatic gain control (AGC) on the basis of the first proportional signal, and can process the output signal generated at the output terminal through at least one partial discharge capacitor in the automatic gain control process to feed back to the feedback terminal corresponding to the other input terminal. In one embodiment, the first automatic gain control unit 1120 can perform feedback through at least one partial discharge capacitor and at least one resistor.

In one embodiment, the first automatic gain control unit 1120 can perform automatic gain control when the first transfer function signal V1′ is input from the proportional signal generation unit 1110, and processes the partial discharge detection signal Vf1 with the automatic gain control feedback signal Vf1′ generated through the at least one partial discharge capacitor in the process of automatic gain control to transmit the partial discharge detection signal Vf to the feedback terminal, thereby causing the partial discharge detection signal Vf to be modified according to whether the partial discharge signal is included. For example, the first automatic gain control unit 1120) If the partial discharge signal is included in the input signal Vin, the partial discharge detection signal Vf including the high frequency component can be generated according to the characteristic of the corresponding partial discharge signal and the automatic gain control feedback signal Vf1′ can be modified through at least one partial discharge capacitor to be fed back to the feedback terminal, thereby inducing a signal deformation of the partial discharge detection signal Vf according to the high frequency component by modifying the gain in the automatic gain capacitor (the case of the partial discharge in the graph of FIG. 16). If not, it may not induce a signal modification of the partial discharge detection signal Vf (a case of partial discharge-like noise or communication noise in the graph of FIG. 16). This is described in more detail with reference to FIG. 13.

FIG. 13 is a block diagram of the first automatic gain control unit and the second automatic gain control unit shown in FIG. 10. More specifically, FIG. 13 shows the first automatic gain control unit 1120, and FIG. 13 shows the second automatic gain control unit 1130.

Referring to FIG. 13, the first automatic gain control unit 1120 may include an AGC module 4100 and a partial discharge feedback module 4200.

The AGC module 4100 may perform automatic gain control on the incoming signal and, in one embodiment, may be implemented with an Automatic Volume Control (AGC) or Automatic Volume Control (AGC), which is a closed loop feedback control circuit that provides a controlled signal amplitude based on the amplitude variation of the signal being fed back at the output despite changes in the amplitude of the input signal. An AGC (Automatic Gain Control) module 4100 reduces the volume of a signal outputted by reducing a gain when the intensity of an input signal is strong, increases a gain of a signal, increases a volume of an output signal, and dynamically controls an input/output gain based on an average signal level or a maximum output signal level of an automatic gain control feedback signal fed back to a feedback terminal.

The partial discharge feedback module 4200 is connected to the output terminal of the AGC module 4100 and the feedback terminal, and processes the output signal of the AGC module 4100 to feed back to the feedback terminal. The partial discharge feedback module 4200 may further include at least one partial discharge capacitor 4200a and at least one partial discharge resistor 4200b, each connected at one end to at least one of an output terminal and a feedback terminal of the AGC module 4100.

In one embodiment, the partial discharge feedback module 4200 may feedback the automatic gain control feedback signal Vf1′ formed through processing of the partial discharge detection signal Vf1 at the feedback end of the AGC module 4100 via the parallel configuration of the at least one partial discharge capacitor 4200a and the at least one partial discharge resistor 4200b. For example, when the partial discharge signal component is reflected in the output partial discharge detection signal, the partial discharge feedback module 4200 can induce temporary over-amplification and fluctuation by changing the amplification degree g of the AGC module 4100 by the charge-discharge and feedback action between the partial discharge capacitor 4200a and the partial discharge resistor 4200b consisting of the RC parallel circuit.

More specifically, the partial discharge signal is a burst composed of a high frequency component having a pulse width of several ns, while noise can be viewed as a cluster of relatively low frequency components having a wide pulse width. As an example, through the log detector circuit, the partial discharge burst is in the form of an impulse, and noise is in the form of a smooth triangular wave. The impulse type waveform consists of a high frequency component in the frequency spectrum and the smooth triangular wave is composed of a relatively low frequency component, so that the response in the partial discharge feedback module 4200 consisting of the RC parallel circuit is different from each other. In one embodiment, the impulse is responsive to the impulse but not the smooth triangular wave in the RC parallel circuit of the partial discharge feedback module 4200 consisting of a particular R value and a C value (see the graph of FIG. 16).

When the partial discharge detection unit 4200 receives the automatic gain control signal from the output terminal of the automatic gain control unit 4100, the partial discharge detection unit 4200 through an RC parallel circuit comprised with a capacitor and a resistor each having an appropriate value and connected to the corresponding output terminal and includes forms charge-discharge feedback, and can lower the intensity of eventually a output signal result from lower the high frequency contents included in a feedback of automatic control signal, and, can let automatic gain control unit 4100 generate temporarily over-amplification and fluctuation as a feedback by feed backing a automatic gain control signal in which high frequency content is lowered to automatic gain control unit 4100.

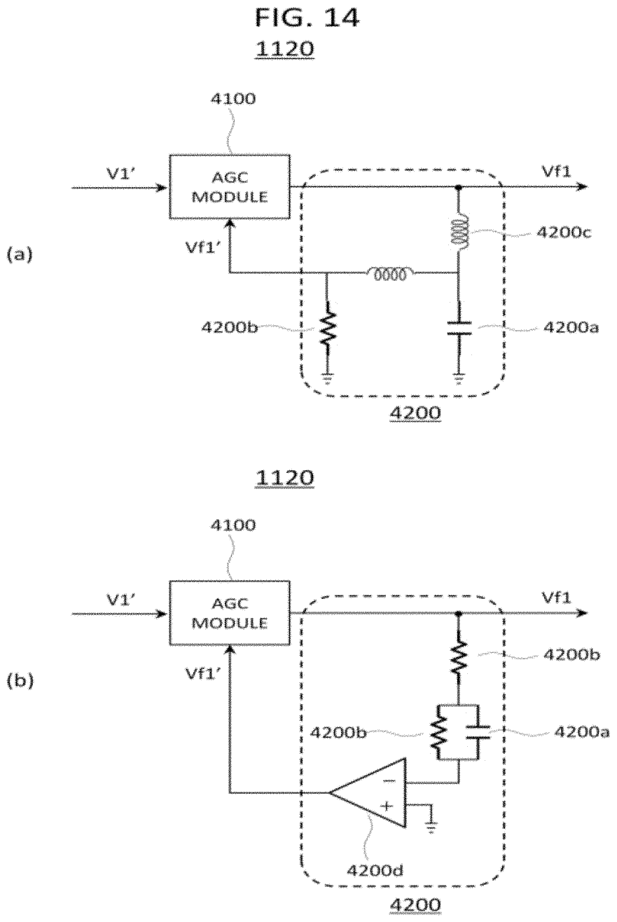

The partial discharge feedback module 4200 may be implemented through configurations of other various embodiments. In one embodiment, partial discharge feedback module 4200. This may be implemented as at least one RC parallel circuit consisting of a single capacitor and a single resistor, as described above, and in other embodiments, as shown in FIG. 14, at least one partial discharge capacitor 4100a. At least one partial discharge resistor 4200b, at least one partial discharge inductor 4100c, and at least one partial discharge amplifier 4100d can be configured through various combinations of configurations, including, but not limited to, at least one partial discharge resistor 4200b, at least one partial discharge inductor 4100c, and at least one partial discharge amplifier 4100d.

The first automatic gain control unit 1120 feeds back the amplitude or frequency of the partial discharge detection signal through the at least one partial discharge capacitor 4200a to the input terminal to reflect the partial discharge signal to the corresponding partial discharge detection signal, thereby inducing transient over-amplification in the process of automatic gain control.

For example, when the partial discharge signal is included in the input signal Vin, the first automatic gain adjuster 1120 performs the automatic gain control on the transfer function signal V1′ that is input by reflecting the partial discharge signal component. Can generate the partial discharge detection signal Vf1 reflecting the partial discharge signal component, and receives the processed automatic gain control feedback signal Vf1′ through the partial discharge feedback module 4200 to temporarily increase the voltage gain for automatic gain control. It is possible to perform temporary over-amplification by auto-adjusting so as to output the partial discharge detection signal Vf1 modified compared to the transfer function signal V1′ through this process (case of partial discharge in the graph of FIG. 16). As another example, if the partial signal is not included in the input signal Vin, the first automatic gain adjuster 1120 adjusts the automatic gain with respect to the transfer function signal V1′ that is input by reflecting the partial discharge-like noise or the communication noise component. In the process of performing the feedback through the partial discharge feedback module 4200, which is not separately processed, the automatic gain control feedback signal Vf1′ can be controlled so that the voltage gain for automatic gain control is automatically adjusted so that there is no temporary over-amplification. Through the process, it is possible to output the partial discharge detection signal Vf1 unmodified or less than the reference range compared to the transfer function signal V1′ (case of partial discharge-like noise or communication noise in the graph of FIG. 16). As a result, the first automatic gain adjusting unit 1120 may output the partial discharge detection signal Vf1 having different waveform characteristics depending on whether the partial discharge signal is included.

In one embodiment, the first automatic gain control unit 1120 may control the voltage gain control factor g to output a partial discharge detection signal with a voltage gain corresponding to the calculated voltage gain control factor g based on Equation 4 below, and may control the voltage gain control factor g in real time in accordance with feedback through the partial discharge feedback module 4200 to reflect voltage gain control.

For example, assuming a partial discharge occurrence situation, as shown in FIG. 16, the first automatic gain control unit 1120 can temporarily amplify a voltage gain by outputting a voltage gain control factor g in high after receiving feedback of automatic control feedback signal Vf1′, being from the partial discharge detection signal Vf1 outputted in real time, which was transformed in intensity of amplitude and frequency by partial discharge feedback module 4200, and, immediately reflect a generation of partial discharge on partial discharge detection signal Vf1 by execution on temporary over-amplification toward the first transfer function signal V1′(or the first proportional signal V1′) with respect to the lowering of feedback input according to the temporary increase, and consequently, the temporarily-amplified partial discharge detection signal Vf1 can be outputted from the corresponding time point through a series of feedback. In one embodiment, the automatic gain control unit 1130 may perform an automatic gain control so that an average voltage gain is 1 when such temporary over-amplification is not executed.

In one embodiment, the automatic gain control unit 1130 may temporarily have a partial discharge signal of a higher or lower fluctuation wave signal value on the basis of Vref as a result of the transient over-amplification in the signal interval containing the partial discharge signal, while the automatic gain control unit 1130 may have a lower value of noise signal than Vref in the absence of the partial discharge signal. See Vf1 in the graph of FIG. 16.

$$g = \frac{{v}_{1}^{′}}{{v}_{f 1}^{′}} \\ {v}_{f 1} = g \times {v}_{1}^{′} \qquad [ Equation 4 ]$$

Where g denotes a voltage gain control factor, v₁′ denotes a transfer function signal, v_{f1} denotes a partial discharge detection signal, and V_{f1′} denotes an automatic gain control feedback signal.

The first automatic gain control unit 1120 filters a specific frequency band from the partial discharge detection signal through at least one partial discharge capacitor 4200a whose one end is connected to the output terminal and the other end is grounded, and feeds back to the corresponding automatic gain control process. In one embodiment, the first automatic gain control unit 1120 can filter the high frequency signal out of a predetermined specific frequency band in the frequency response characteristic of the partial discharge detection signal through the partial discharge feedback module 4200 configured in the RC parallel circuit, and feed back the modified partial discharge feedback signal from the partial discharge detection signal to the automatic gain control process of the AGC module 4100 during the filtering process. For example, the partial discharge feedback module 4200 may function as a low pass filter (LPF) through this RC coupling configuration, and may feedback the AGC module 4100 with an automatic gain control feedback signal, Vf1′ in which a signal over the 500 MHz frequency band is filtered, for example, at the partial discharge detection signal Vf1.

At this time, in one embodiment, the partial discharge capacitor 4200a can be designed to have a capacitance value of 30 pF to 300 pF, and the partial discharge resistor 4200b can be designed to have a value of several hundred kOhm at a few kOhm according to the capacitor design range of the partial discharge capacitor 4100a, and can be designed to have a resistance value of 20 kOhm to 40 kOhm, and can control the element value by considering the length pattern width of the PCB pattern design pattern and the dielectric constant of the material.

As described above, in one embodiment, the feedback module 4200 may perform feedback via at least one partial discharge capacitor 4200A and at least one partial discharge resistor 4200B, and in another embodiment, may perform feedback via a low pass filter (LPF) or a high pass filter (HPF) implemented through at least two of a capacitor, an inductor, a resistor, and an amplifier. For example, as in FIG. 14(a), the feedback module 4200 may be comprised of a partial discharge capacitor 4200a, a partial discharge resistor 4200b, and a partial discharge inductor 4200c, and may function as an LPF through such a coupling configuration. For another example, as shown in FIG. 14, the partial discharge feedback module 4200 may be comprised of a capacitor 4200a, a partial discharge resistor 4200b, and a partial discharge amplifier 4200d, and may function as an LPF through such a coupling configuration.

Although exemplary configurations for implementing the partial discharge feedback module 4200 have been described above, it should be understood that the partial discharge feedback module 4200 is not limited thereto, but may be configured in various forms as necessary in connection with the function of modifying and feeding back the output signal of the AGC module 4100 for partial discharge detection to induce an over-amplification and a fluctuation wave operation when the partial discharge is generated.

The second automatic gain control unit 1130 performs automatic gain control based on the partial discharge comparison signal generated based on the second proportional signal and fed back to the input terminal.

Referring to FIG. 13, the second automatic gain control unit 1130 may include an AGC module 4100. In one embodiment, the second automatic gain control unit 1130 may perform automatic gain control with respect to the input received through the AGC module 4100 when the second proportional signal or the second transfer function signal is received, and feeds back the output signal to the feedback terminal of the input terminal to generate a partial discharge comparison signal.

For example, the second automatic gain control unit 1130 performs automatic gain control on the second proportional signal (or the second transfer function signal VT) received regardless of whether the partial discharge signal is included or not. It is not deformed compared to the second proportional signal (or second transfer function signal VT) through a series of processes for generating the partial discharge detection signal Vf2 and feeding back the partial discharge detection signal generated in the process of automatic gain control to the feedback stage. The partial discharge comparison signal Vf2 modified below the reference range may be output (see the graph of FIG. 16). As a result, the partial discharge detection signal Vf1 generated by the first automatic gain adjuster 1120 and the partial discharge comparison signal Vf2 generated by the second automatic gain adjuster 1130 are included in the input signal. It can be output as an analog signal having a different value depending on whether or not.

The first automatic gain control unit 1120 and the second automatic gain control unit 1130 may further include a resistance of a few kOhm disposed between the first automatic gain control unit 1120 and the input terminal of the timing noise elimination unit 1140 in order to control the output impedance in the process of transmitting the output signal to the input terminal of the timing noise elimination unit 1140.

The timing noise elimination unit 1140 generates a noise cancellation signal in which the partial discharge noise is removed based on the partial discharge detection signal and the partial discharge comparison signal. For example, the timing noise elimination unit 1140 may perform filtering on the basis of the reference voltage with respect to the input two signals to generate a noise cancellation signal, and may generate a noise cancellation signal by buffering or amplifying or subtracting only a portion of the partial discharge detection signal and the partial discharge comparison signal based on the reference voltage.

The timing noise elimination unit 1140 may cancel a difference between the partial discharge detection signal and the partial discharge comparison signal or may sum a similar portion to remove components other than the partial discharge as noise. In one embodiment, the timing noise removal unit 1140 may compare the difference between the partial discharge detection signal Vf1 and the partial discharge comparison signal Vf2, determine the corresponding similar portion as noise, remove the remaining portion, and generate a noise cancellation signal Vout(denoise) (see the graph of FIG. 16).

In an embodiment, the timing noise removing unit 1140 may include a differential amplifier or a partial discharge detection signal and the comparison partial discharge detection signal that calculate a difference between the partial discharge detection signal and the partial discharge comparison signal. It can be implemented through a differential amplifier that differentially amplifies the liver. For example, the timing noise removing unit 1140 generates a noise removing signal by subtracting the partial discharge comparison signal from the partial discharge detection signal to generate a noise removing signal, and a differential amplifier using a +5 Vdc single power supply as an operating power source. Or a differential amplifier that differentially amplifies the difference between them based on a reference voltage or any particular voltage to generate a noise cancellation signal.

In one embodiment, the timing noise elimination unit 1140 may cancel the difference signal through a subtraction operation between the partial discharge detection signal and the partial discharge comparison signal, and restore the original signal through the inverse process of the proportional signal generation process from the erased signal to generate a noise cancellation signal. For example, the timing noise elimination unit 1140 may generate the noise cancellation signal Vout by modulating the log value of the corresponding signal after erasing the partial discharge comparison signal Vf2 in the partial discharge detection signal Vf1.

In another embodiment, the timing noise removing unit 1140 may determine and obtain a difference between the partial discharge detection signal and the partial discharge comparison signal as partial discharge timing noise, and may obtain the signal distribution module 1112 from the input signal. By canceling the difference between Vin′ and Vin″ distributed to have the same amplitude, a timing noise cancellation signal can be generated.

The timing noise elimination unit 1140 may further include a timing noise removal module (not shown) that removes a signal output to a strength less than a specific reference voltage among the output signals for further removal of the timing noise. For example, the timing noise elimination unit 1140 may generate a timing noise cancellation signal in which the timing noise component is additionally removed by dropping a voltage, which is raised according to the occurrence of a partial discharge through a timing noise removal module including at least one diode, to a certain specific voltage, a reference voltage, or a reference voltage.

The timing noise elimination unit 1140 may determine the specific reference voltage for further removal of the timing noise through manual setting by the user or automatic setting through the internal feedback.

In one embodiment, the timing noise elimination unit 1140 may perform a manual setting based on a local analog voltage according to a variable resistance manually varied by a user at a local time, a remotely provided remote analog voltage, or a Digital to Analog Converter (DAC) output by remotely provided remote digital data transmission. For example, the timing noise elimination unit 1140 may include an input means for receiving a variable resistance input by a user, and if a variable resistance value is specified by the user at a local user, the variable resistor may be set to a corresponding designated variable resistance value to determine the resulting analog voltage to the particular reference voltage. For example, the timing noise elimination unit 1140 may receive a variable resistance value designated by a corresponding user from an external partial discharge processing server (not shown) or a partial discharge processing terminal (not shown) that is remotely connected through a remote communication module embedded in the partial discharge timing signal acquisition unit 1100.

In another embodiment, the timing noise elimination unit 1140 may include a low pass filter (not shown) and a feedback module (not shown). Here, the low pass filter may be disposed at the output stage to filter the timing noise cancellation signal, and the feedback module may detect the lowest, average, or peak of the filtered timing noise cancellation signal through the ADC conversion and the digital operation and feedback until the corresponding detection value converges to within a particular reference range to automatically set the particular reference voltage. For example, when the timing noise cancellation signal is generated, the timing noise elimination unit 1140 filters the remaining signal except the specific frequency region set by the user in association with the low frequency in the timing noise cancellation signal through the low-frequency pass filter disposed at the output terminal, and repeats the ADC conversion and the digital calculation process until the average value of the filtered timing noise cancellation signal is confirmed within the predetermined reference average value range so that the specific reference voltage can be automatically set in this process.

The timing signal generation unit 1150 recognizes the timing noise cancellation signal as a partial discharge generation timing when the timing noise cancellation signal is equal to or greater than a reference amplitude and generates a separate partial discharge notification signal converted to a transistor logic (TTL) level, and in one embodiment, can generate a partial discharge notification signal to have a specific amplitude and duration. Here, the reference amplitude can be set by the designer based on a design target relating to accuracy and speed, and the design values of the internal components can be controlled to have the corresponding reference amplitude.

In one embodiment, the timing signal generation unit 1150 may further generate a partial discharge generation timing signal by pulsing a transistor logic (TTL) signal using a Schmitt trigger circuit, which is obtained by a differential amplifier or a differential amplifier.

In one embodiment, TTL pulsing may be further implemented using a comparator or via an analog-to-digital conversion. More specifically, the timing signal generation unit 1150 can acquire the partial discharge generation timing through the generated partial discharge generation timing signal.

In one embodiment, the timing signal generation unit 1150 may be implemented including at least one of a comparator and a Schmitt-trigger to perform the conversion to the TTL level.

For example, when the amplitude difference between the partial discharge detection signal and the partial discharge comparison signal is greater than or equal to a specific reference voltage Vt, the timing signal generator 1150 may set a specific voltage level representing data 1 (high) for a specific duration. A comparator that generates (e.g., clockwise), a level trigger or edge trigger, and a voltage level that triggers whether the output of the comparator indicates data 1 (high) It may be implemented including a combination of at least one of a level shifter for adjustment. Accordingly, the timing signal generator 1150 may provide a partial discharge notification signal having a TTL level for digital signal processing to be used as an input for digital processing in a later step.

In one embodiment, the partial discharge timing signal acquisition unit 1100 may further include a network communication module, and may output a warning sound when a partial discharge notification signal is generated and transmit information about the corresponding waveform to a partial discharge processing server or a partial discharge processing terminal connected to the network through the network communication module. In addition, the partial discharge timing signal acquisition unit 1100 measures the intensity of the partial discharge timing signal using the ADC converted digital signal and monitors the partial discharge intensity variation through analysis according to the intensity of each time zone, and can be used as facility remote monitoring and remote preventive diagnosis equipment.

Blank

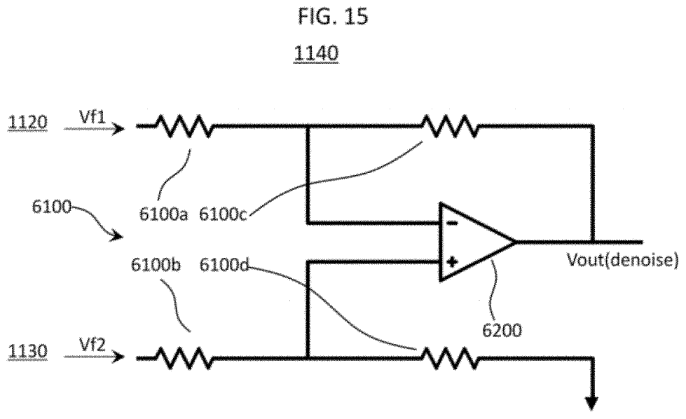

FIG. 15 is a circuit diagram of the timing noise elimination unit shown in FIG. 10.

Referring to FIG. 15, the timing noise elimination unit 1140 may be comprised of a differential amplifier 6200 that receives a partial discharge detection signal Vf2 as a first input, receives a partial discharge comparison signal Vf1 as a second input and subtracts a second input at a first input. In one embodiment, the timing noise elimination unit 1140 may function as a subtraction to amplify a difference in the intensity of the positive input to a voltage gain 1 using an operational amplifier, and in another embodiment, may function as a differential amplifier that uses an operational amplifier to amplify the difference in intensity of the positive input to a voltage gain greater than or equal to 1.

In an embodiment, the timing noise remover 1140 may receive the partial discharge detection signal and the partial discharge comparison signal through the plurality of resistors 6100, and for example, the second automatic gain control unit 1130. An output terminal and a dipper of the first resistor 6100a and the second automatic gain control unit 1130 that are disposed between the output terminal 1130 and the first input terminal of the difference amplifier 6200 to transmit the first partial discharge detection signal Vf1. The second resistor 6100b disposed between the second input terminal of the difference amplifier 6200 and transmitting the second partial discharge detection signal Vf2, and a third disposed and fed back between the first input terminal and the output terminal of the differential amplifier 6200. The resistor 6100c may include a fourth resistor 6100d disposed between the second input terminal and the ground of the difference amplifier 6200. In one embodiment, the plurality of resistors 6100 may be designed to have the same resistance value with each other within a resistance range of several kOhm.

Blank

FIG. 16 is a diagram illustrating voltages that the partial discharge noise suppression and signal processing system of FIG. 9 receives or outputs a timing signal, a partial discharge detection, a partial discharge, or a production process.

In FIG. 16, the partial discharge timing signal acquisition unit 1100 may receive an input signal Vin via an input port 4, and the proportional signal generation unit 1110 may generate a first proportional signal V1 and a second proportional signal V2 that are proportional to the strength of the input signal Vin (e.g., demodulate a log value of Vin). For example, among the RF burst signals that have been de-modulated by the proportional signal generation unit 1110, the portion corresponding to the partial discharge signal may be output to the proportional signals V1 and V2 having a waveform close to a very narrow waveform width (e.g., an impulse), and noise other than the partial discharge may be output to the proportional signals V1 and V2 having a relatively slow waveform.

As described above, the proportional signal generation unit 1110 can generate the first and second transfer function signals V1′ and V2′ corresponding to the first and second proportional signals V1 and V2, respectively, according to the characteristics of the set reference voltage Vref and the slope of the transfer function (e.g., Slope=(VO2−VO1)/(PI2−PI1)). Here, Pi is the intensity of the RF sweep burst input shown in the generation process of the corresponding transfer function signal.

The first automatic gain control unit 1120 performs automatic gain control on the input first transfer function signal V1′ and converts the partial discharge detection signal Vf1 output from the automatic gain control process to the partial discharge feedback signal Vf1′ through the partial discharge feedback module 4200 configured in the RC parallel circuit to transmit the partial discharge detection signal Vf1 to the feedback terminal of the AGC module 4100 to output the partial discharge detection signal Vf1. The first automatic gain control unit 1120 feeds back the automatic gain control feedback signal Vf1′, which temporarily drops the voltage in the high frequency band from the partial discharge detection signal through the partial discharge feedback module 4200, to the AGC module 4100, increases the voltage gain through the AGC module 4100 according to the feedback, and over-amplifies the amplitude of the partial discharge detection signal Vf1 outputted while the corresponding drop continues.

In FIG. 16, in the case where a partial discharge signal is included in the input signal Vin, the modified partial discharge detection signal Vf1 may be generated with respect to the first transfer function signal, and if the partial discharge-like noise or the communication noise is included, a substantially unmodified partial discharge comparison signal Vf2 may be generated. For convenience, the partial discharge detection signal Vf1 and the automatic gain control feedback signal Vf1′ are separately illustrated, but may be represented as substantially the same node voltage depending on the implementation or the parasitic element on the layout design.

The timing noise elimination unit 1140 may remove the partial discharge timing noise based on the difference between the partial discharge detection signal Vf1 and the partial discharge comparison signal Vf2 to output the timing noise cancellation signal VOUT. The timing noise elimination unit 1140 removes a difference between the partial discharge detection signal Vf1 and the partial discharge comparison signal Vf2, or sums similar parts to remove components other than the partial discharge as timing noise. In one embodiment, the timing noise elimination unit 1140 generates a partial discharge timing signal after erasing the difference portion through a subtraction operation between the partial discharge detection signal Vf1 and the partial discharge comparison signal Vf2, detects only a partial discharge by using the partial discharge timing signal, generates a partial discharge signal similar to the original signal, or generates a partial discharge signal similar to the original signal through the inverse process of the proportional signal generation process, thereby generating the pure partial discharge signal Vout with the partial discharge noise removed.

The timing noise elimination unit 1140 may remove a signal output to a strength smaller than a specific reference voltage among the output signals in order to additionally reduce some remaining noise components, thereby completing a noise cancellation signal Vout(denoise).

When the difference between the partial discharge detection signal and the partial discharge comparison signal is greater than or equal to the Vt threshold, the timing signal generation unit 1150 may generate a partial discharge notification signal Vout(timing) of the ITI-level. When the difference between the partial discharge detection signal and the partial discharge comparison signal as a reference voltage applied to a comparator (not shown) is greater than or equal to a Vt threshold, a positive TTL sweep signal is generated, and if the difference between the partial discharge detection signal and the partial discharge comparison signal is less than the Vt threshold, a zero potential is output.

According to the embodiments, the partial discharge timing signal acquisition unit 1100 can selectively perform feedback according to whether a partial discharge signal is included in the input signal to generate a differential timing noise cancellation signal, and if it is determined that a partial discharge signal is included, the partial discharge timing signal acquisition unit 1100 can generate and inform a partial discharge notification signal.

Blank

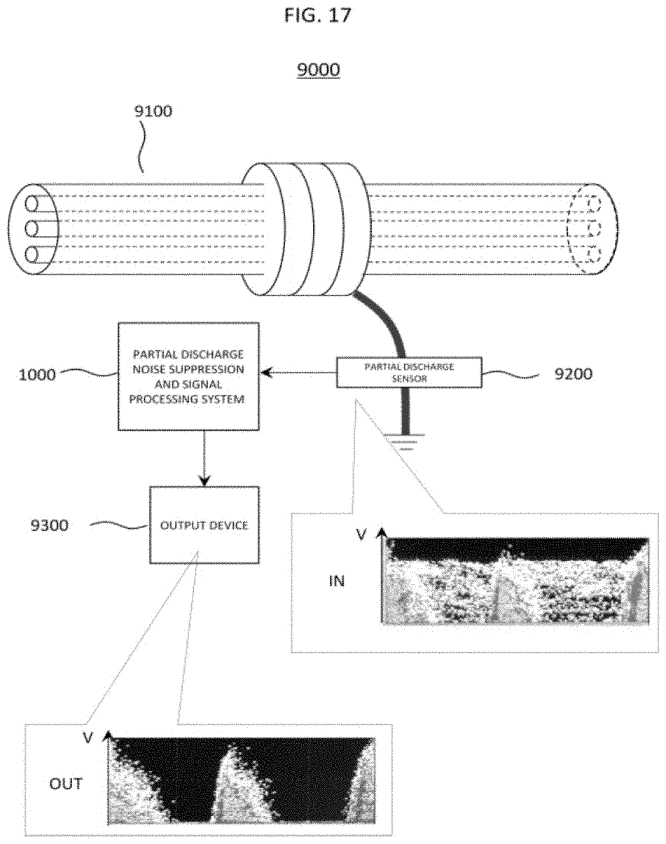

FIG. 17 shows experimental results of removing noise and detecting partial discharge using the partial discharge noise suppression and signal processing system shown in FIG. 9.

Referring to FIG. 17, the partial discharge detection system 9000 may include an electric device 9100, a partial discharge sensor 9200, a partial discharge noise suppression and signal processing system 1000, and an output device 9300.

The electrical equipment 9100 may correspond to a power plant device that performs at least one of electric, power generation, electrical conversion, electricity supply, and electrical control. For example, the electrical equipment 9100 may correspond to a cable partial discharge device that includes a Solid Insulated Switchgear (SIS). In FIG. 8, the electric equipment 9100 is shown in the form of a gas insulated switchgear, but may correspond to a battery, an inverter, a power motor, a charger for an electric vehicle, a transformer, or a cable on an electric vehicle, and may correspond to a high-speed electric steel or a building distribution and a Ultra High Frequency (UHF) related device.

The partial discharge sensor 9200 may be coupled to a ground line of the electrical equipment 9100, may be implemented as a current SIA transformer (CT) that detects electromagnetic waves generated by the electric equipment 9100 and converts it into a current, and the partial discharge noise suppression and signal processing system 1000 receives the current converted from the partial discharge sensor 9200 as an input signal, discharges the partial discharge timing signal based on the input signal, and performs partial discharge detection by detecting only the partial discharge signal.

The output device 9300 can be coupled to the partial discharge timing signal acquisition unit 1100, and can process the signals received from the partial discharge noise suppression and signal processing system 1000 to visualize the PRPD phase with a phase-resolved electromagnetic discharge (PRPD) or a phase-resolved pulse sequence (PRPS). In one embodiment, the output device 9300 may be implemented via at least one of a digital conversion module capable of converting analog signals received from the partial discharge timing signal acquisition unit 1100 into a digital signal, a field-programmable gate array (FPGA) implemented to be programmable based on the converted digital signal, a PC board for processing a signal received from the FPGA manufacturer, and a display module for visually outputting the processed signal.

Blank

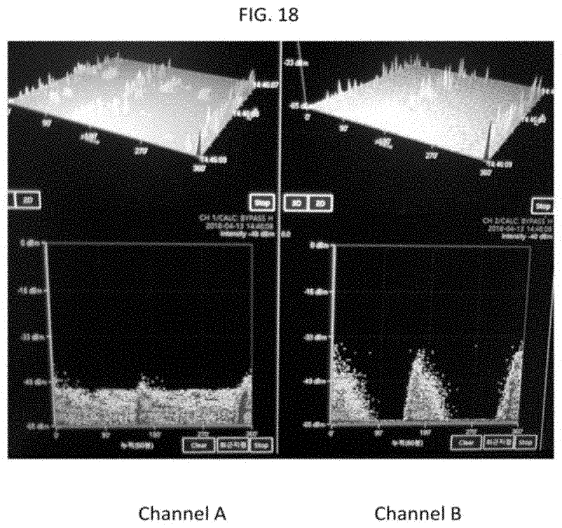

FIG. 18 is a graph showing the result of comparing the partial discharge noise suppression and signal processing system 1000 shown in FIG. 9 with the prior art to detect whether a partial discharge occurs.

In FIG. 9, the partial discharge noise suppression and signal processing system 1000 may be implemented with actual equipment to receive a target signal as an input signal from a partial discharge sensor 9200 connected to the electrical equipment 9100 of the SIS equipment, process the provided input signal to detect whether a partial discharge signal is included, and visualize the corresponding input/output signal through the output device 9300.

In FIG. 18, channel A in the illustrated graph represents the input signal Vin provided from the partial discharge sensor 9200 without going through the inventive device, and channel B is the comparison graph of the input signal Vin provided from the partial discharge sensor 9200 via the inventive device. According to an embodiment of the present invention, the device for acquiring the partial discharge timing signal acquisition unit 1100 can suppress noise in the provided input signal Vin and detect whether the partial discharge signal is included in a high degree of accuracy.

Blank

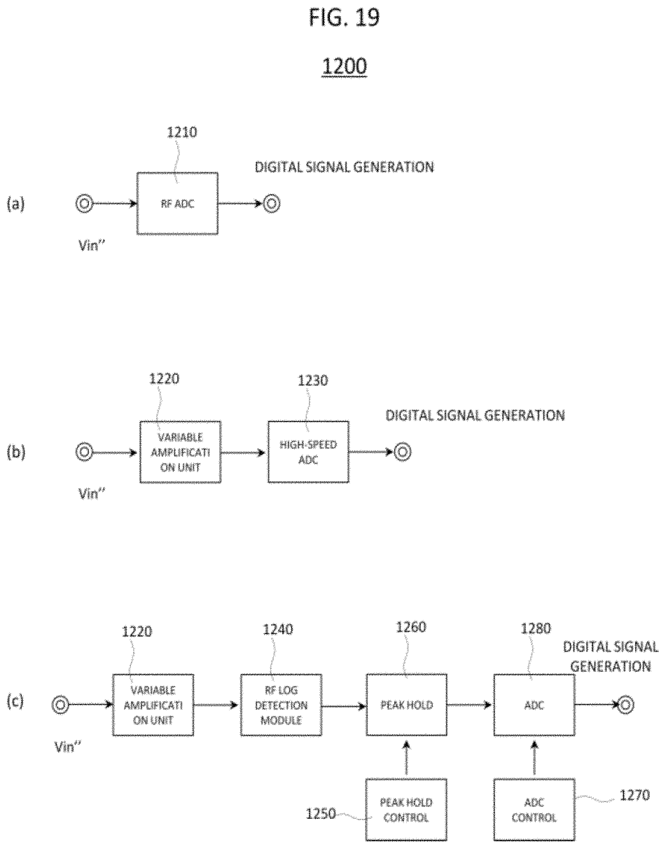

FIG. 19 is a view showing the partial discharge signal acquisition unit shown in FIG. 9.

Referring to FIG. 19, the partial discharge signal acquisition unit 1200 may include a variable amplification unit 1220, an RF log detection module 1240, a peak hold 1260, a peak hold control 1250, an ADC control 1270, an ADC 1280, a high-speed ADC 1230, and an RF ADC 1210.

In one embodiment, the partial discharge signal acquisition unit 1200 can use the first, second, and third analog-todigital converters according to the speed of the ADC conversion. Here, the first, second, and third analog-to-digital converters may correspond to an RF ADC, a high-speed ADC, and a general ADC, respectively.

In one embodiment, the general ADC may operate from a sampling rate up to 1 Msps, a high-speed ADC may run from 250 Msps to 1 Gsps, and an RF ADC may run up to a few Gsps.

In one embodiment, for RF ADC operation, the input RF signal is directly sampled at the RF level without going through a modulation process, and the control unit may obtain a partial discharge signal value corresponding to the timing noise cancellation signal (i.e., the RF value at the partial discharge timing). In this case, the RF FPGA can be operated.

In one embodiment, in the case of a high-speed ADC operation, a signal amplified or attenuated in a variable amplification unit controlled by a control unit without a special modulation process can be sampled at high speed to pass the signal to a control unit, and a partial discharge signal value can be obtained at a partial discharge timing in the control unit.

In one embodiment, when a general ADC operation is used, an input signal is amplified or attenuated according to a control, and a peak hold method for storing a maximum value in a capacitor by modulating the input signal with an RF log detection module can be used, the peak hold value is sampled and transmitted to a control unit to obtain a partial discharge value, and the control unit resets a peak hold capacitor to prepare a next value. In this case, the peak hold period, the peak hold time, and the reset timing can be determined in the control unit.

Blank

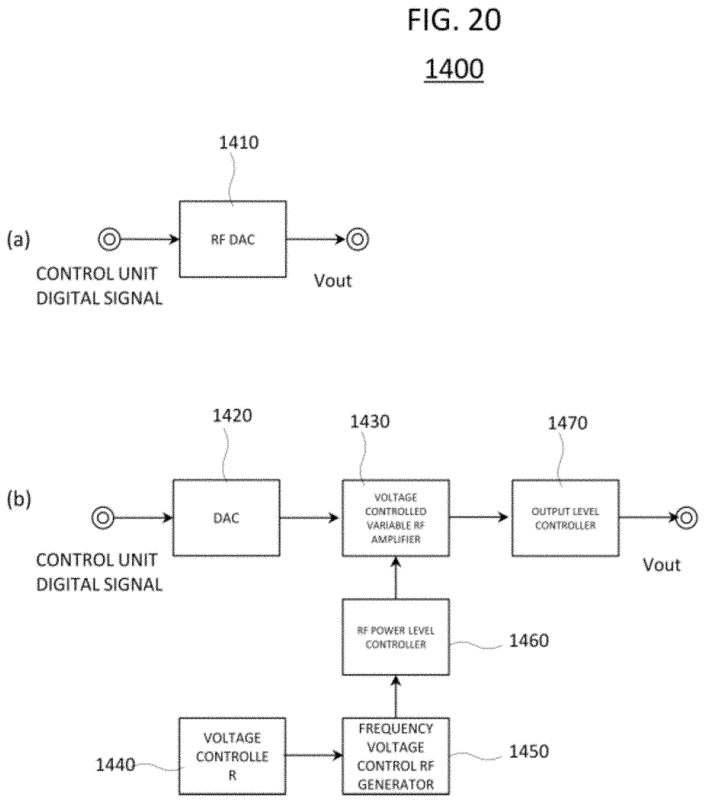

FIG. 20 is a diagram illustrating the configuration of the partial discharge signal generation unit shown in FIG. 9 according to an embodiment of the present invention.

Referring to FIG. 20, the partial discharge signal generation unit 1400 may include a voltage controller 1440, a frequency voltage control RF generator 1450, an RF power level controller 1460, a voltage controlled variable RF amplifier 1430, an output level controller 1470, a DAC 1420, and an RF DAC 1410.

In one embodiment, the partial discharge signal generation unit 1400 can selectively operate a connection method (hereinafter, topology) of a circuit configuration according to the speed of the DAC. More specifically, the partial discharge signal generation unit 1400 can selectively use the first or second digital-to-analog converter according to the speed of the DAC. Here, the first digital-to-analog converter may correspond to an RF DAC and the second digital-to-analog converter may correspond to a general DAC. The RF DAC can directly produce an RF sweep signal of 500 MHz or more such that there is no separate additional topology, in which case the RF RNIC can operate the FPGA, and the Direct Digital Synthesizer Manufacturer (DDS) can operate the high-speed RF DAC in a simplified topology in which the functions of the SDR (Software Define Radio) algorithm are involved. The general DAC can be operated with a number Msps.

In one embodiment, in the case of general DAC operation, a frequency voltage controlled RF generator 1450 such as a voltage control oscillator (VCO) may be operated, and the control voltage of the device may be supplied from a controller or supplied alone. Can be controlled by The generated RF signal is supplied to the voltage controlled variable RF amplifier 1430 at an appropriate level through an RF level controller 1460 such as an attenuator. The amplification degree of the device is controlled by the voltage waveform supplied from the DAC 1420. To generate an RF burst. The generated RF burst may be appropriately adjusted by the output level adjusting unit 1470 such as an attenuator and may be output as a Vout 2 signal.

Blank

While the invention has been particularly shown and described with reference to preferred embodiments thereof, it will be understood by those skilled in the art that various changes in form and details may be made therein without departing from the spirit and scope of the invention as defined by the appended claims.

Blank

### DESCRIPTION OF THE DRAWINGS

100: Partial discharge processing device
110: Proportional Signal Generation Unit 120: Transfer Function Generation Unit
130: Automatic Gain Control Unit 140: Partial Discharge Detection Unit
150: Partial Discharge Determination Unit
1000: Partial Discharge Noise Suppression And Signal Processing System
1100: Partial discharge timing signal acquisition unit
1200: Partial discharge signal acquisition unit
1300: Control Unit
1400: Partial Discharge Signal Generation Unit

The invention claimed is:

1. A partial discharge processing device comprising:
a proportional signal generation unit configured to generate a proportional signal which is proportional to a strength of an input signal;
a transfer function generation unit which is positioned between an output terminal of the proportional signal generation unit and an input terminal of an AGC (automatic gain control) unit, configured to convert, on the basis of a reference voltage and a transfer function, the proportional signal which is inputted into a input terminal, and output a transfer function signal;
an automatic gain control unit which is configured to perform automatic gain control when the transfer function signal is inputted;
a partial discharge detection unit which is configured to generates an automatic gain control feedback signal through at least one RC parallel circuit to feedback the AGC feedback signal to a feedback terminal of the AGC unit, when an automatic gain control signal of the automatic gain control unit is inputted; and
a partial discharge determination unit which is configured to filter the automatic gain control output signal on the basis of the reference voltage to generate a partial discharge determination signal, when the automatic gain control output signal of the automatic gain control unit is inputted.

2. The partial discharge processing device of claim 1, wherein the proportional signal generation unit includes a log detector that demodulates a log value of the.

3. The partial discharge processing device of claim 1, wherein the proportional signal generation unit is implemented through at least one of an amplifier, an envelope detector, and an integrator or through at least two combinations.

4. The partial discharge processing device of claim 1, wherein the partial discharge detection unit feedbacks an strength of amplitude or a frequency of the automatic gain control signal to feedback terminal of the automatic gain control unit through the at least one RC parallel circuit.

5. The partial discharge processing device as claimed in claim 4, wherein in the feedback process, the partial discharge detection unit performs a negative amplification with respect to the reference voltage when a noise is included in the automatic gain control signal, and induces a temporary over-amplification and fluctuation to change an amplification factor as charging, discharging and feedback effects among the at least one RC parallel circuit and the automatic gain control unit when a partial discharge signal is included.

6. The partial discharge processing device of claim 1, wherein the transfer function generation unit has an inverse proportional transfer function for converting a value of −60 dBm to 5 dBm of the proportional signal to a value of 1.7 Vdc to 0.5 Vdc.

7. The partial discharge processing device of claim 1, wherein the reference voltage is formed to have a value within a specified error range on the basis of 2.4 Vdc.

8. The partial discharge processing device of claim 1, wherein the partial discharge determination unit compares the automatic gain control output signal with the reference voltage to determine and discard a signal which is less than the reference voltage in the automatic gain control output signal as noise, and generates the partial discharge determination signal through the filtering obtained by determining and obtaining the signal which is above the reference voltage as a partial discharge.

9. The partial discharge processing device of claim 1, wherein the partial discharge determination unit is implemented with a difference amplifier which subtracts the reference voltage from the automatic gain control output signal, or implemented with a differential amplifier that differentially amplifies on the basis of the automatic gain control output signal and the reference voltage, or includes at least one diode for voltage drop in partial discharge.

10. The partial discharge processing device of claim 1, further comprising a partial discharge signal level conversion unit for generating a partial discharge level conversion signal converted to a TTL transistor logic level if the amplitude of the partial discharge determination signal is equal to or greater than a reference amplitude.

11. The partial discharge processing device of claim 10, wherein the partial discharge signal level conversion unit is implemented through at least one of a comparator and a Schmitt trigger.

12. A partial discharge detecting method performed by a partial discharge processing device, the method comprising:
a proportional signal generating step of generating a proportional signal proportional to the intensity of the input signal;
a transfer function generation step of setting a reference voltage and a transfer function and converting the proportional signal based on the reference voltage and the transfer function to generate a transfer function signal;
an automatic gain control step of performing Auto Gain Control on the basis of the transfer function signal;
a partial discharge detection step of inducing a mutual charge/discharge and a feedback action between the at least one RC parallel circuit and the automatic gain control unit and feeding them through at least one RC parallel circuit back to a process of performing the automatic gain control; and
a partial discharge determination step of generating a partial discharge determination signal by filtering the automatic gain control output signal based on the reference voltage when an automatic gain control output signal is generated through the automatic gain adjustment.
